(19) United States
(12) Patent Application Publication
(10) Pub. No.: US 2026/0159937 A1
(43) Pub. Date: Jun. 11, 2026

(54) DEPOSITION MASK AND ELECTRONIC DEVICE FABRICATED THEREBY

(71) Applicant: Samsung Display Co., Ltd., Yongin-si (KR)

(72) Inventors: Jeong Kuk KIM, Yongin-si (KR); Young Jin SONG, Yongin-si (KR); Ji Hyun JUNG, Yongin-si (KR)

(21) Appl. No.: 19/270,258

(22) Filed: Jul. 15, 2025

(30) Foreign Application Priority Data
Dec. 5, 2024 (KR) 10-2024-0179555

(51) Int. Cl. C23C 14/04; H10K 59/80; H10K 71/00

(52) U.S. Cl. CPC C23C 14/042; H10K 59/80521; H10K 71/621

(57) ABSTRACT

A deposition mask includes: a mask frame in which a cell opening is formed; a membrane on the upper portion of the mask frame; and an electrode pattern portion on the mask frame.

### CROSS-REFERENCE TO RELATED APPLICATION

The present application claims priority to and the benefit of Korean Patent Application No. 10-2024-0179555, filed on Dec. 5, 2024, in the Korean Intellectual Property Office, the entire disclosure of which is incorporated herein by reference.

### BACKGROUND

### 1. Field

Aspects of some embodiments of the present disclosure relate to a deposition mask and an electronic device fabricated thereby.

### 2. Description of the Related Art

A head-mounted display (HMD) is an image display device that is worn on a user's body in the form of glasses or a helmet to form a focus close to the user's eyes. A head-mounted display can implement virtual reality (VR) or augmented reality (AR).

A head-mounted display magnifies images displayed by a small display device using a plurality of lenses to display the images. Therefore, a display device applied to a head-mounted display may be utilized to provide high-resolution images, for example, images with a resolution of 3,000 PPI (pixels per inch) or higher. To this end, OLEDoS (organic light-emitting diode on silicon), which is a small, high-resolution organic light-emitting display device, is used as the display device applied to a head-mounted display. The OLEDoS is a device that displays images in which organic light-emitting diodes (OLED) are located on a semiconductor wafer substrate including complementary metal oxide semiconductor (CMOS).

In order to fabricate a high-resolution display panel with a resolution of 3,000 PPI or higher, a deposition mask for high resolution may be utilized. For example, a deposition mask may be fabricated by forming a membrane having a plurality of pixel openings on a substrate, such as a silicon wafer, and partially etching the substrate to form cell openings exposing the pixel openings.

Such a deposition mask may be used in a deposition process for forming organic light-emitting layers on a backplane substrate. During a deposition process, the backplane substrate may be located on the deposition mask, and a deposition source may be placed under the deposition mask to provide a vapor deposition material. The vapor deposition material may be deposited on the backplane substrate through the pixel openings of the deposition mask.

The above information disclosed in this Background section is only for enhancement of understanding of the background and therefore the information discussed in this Background section does not necessarily constitute prior art.

### SUMMARY

Aspects of some embodiments of the present disclosure include, a deposition mask capable of relatively improving the deposition precision of an organic light-emitting layer deposited on a backplane substrate and an electronic device fabricated thereby.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a deposition mask includes a mask frame in which a cell opening is formed, a membrane on the upper portion of the mask frame, and an electrode pattern portion on the mask frame.

According to some embodiments, the electrode pattern portion surrounds the cell opening in a state of being spaced apart from the cell opening.

According to some embodiments, the cell opening is provided in plural numbers, and the electrode pattern portion is between the cell openings.

According to some embodiments, the electrode pattern portion is introduced into the interior of the mask frame from the upper surface of the mask frame.

According to some embodiments, the membrane is divided into a mask cell area on the upper portion of the cell opening and a grid area on the upper portion of the mask frame excluding the mask cell area, and the electrode pattern portion overlaps the grid area.

According to some embodiments, the membrane includes an inorganic layer on the upper portion of the mask frame; and a nitride layer on the upper portion of the inorganic layer, wherein the electrode pattern portion is on the lower portion of the inorganic layer

According to some embodiments, the electrode pattern portion includes a first electrode pattern, and a second electrode pattern spaced apart from the first electrode pattern and having the opposite polarity from the first electrode pattern.

According to some embodiments, the electrode pattern portion further includes an insulating pattern between the first electrode pattern and the second electrode pattern.

According to some embodiments, the cell opening is provided in plural numbers, the plurality of cell openings area being spaced apart in a first direction and a second direction intersecting the first direction, and the electrode pattern portion extends in the first direction and the second direction to surround the plurality of cell openings.

According to some embodiments, the electrode pattern portion extends in a linear form in the first direction and second direction.

According to some embodiments, the electrode pattern portion extends in a curved shape in the first direction and second direction.

According to some embodiments of the present disclosure, an electronic device including a display device manufactured by a deposition mask, wherein the deposition mask includes a mask frame in which a cell opening is formed, a membrane on the upper portion of the mask frame, and an electrode pattern portion on the mask frame.

According to some embodiments, the electrode pattern portion surrounds the cell opening in a state of being spaced apart from cell opening.

According to some embodiments, the cell opening is provided in plural numbers, and the plurality of cell openings are between the cell openings.

According to some embodiments, the electrode pattern portion is introduced into the interior of the mask frame from the upper surface of the mask frame.

According to some embodiments, the electrode pattern portion includes a first electrode, and a second electrode pattern spaced apart from the first electrode pattern and having the opposite polarity from the first electrode pattern.

According to some embodiments, the electrode pattern portion further includes an insulating pattern between the first electrode pattern and the second electrode pattern.

According to some embodiments, the cell opening is provided in plural numbers, the plurality of cell openings are spaced apart in a first direction and a second direction intersecting the first direction, and the electrode pattern portion extends in the first direction and the second direction to surround the plurality of cell openings.

According to some embodiments, the electrode pattern portion extends in a linear form in the first direction and second direction.

According to some embodiments, the electrode pattern portion extends in a curved form in the first direction and second direction.

According to some embodiments of the present disclosure, it may be possible to relatively improve the deposition precision of an organic light-emitting layer deposited on a backplane substrate by forming an electrode pattern portion to surround a cell opening on a mask frame to increase the adhesion between the membrane and the backplane substrate.

The characteristics of embodiments according to the present disclosure are not limited to those mentioned above and more various characteristics are included in the following description of the present disclosure.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is an exploded, perspective view showing a display device according to some embodiments of the present disclosure;

FIG. 2 is a plan view for illustrating the display device shown in FIG. 1;

FIG. 3 is an equivalent circuit diagram showing an example of the first sub-pixel shown in FIG. 2;

FIG. 4 is a plan view showing an example of the display panel shown in FIG. 1;

FIG. 5 is an enlarged plan view showing an example of the display area of FIG. 4;

FIG. 6 is an enlarged plan view showing another example of the display area of FIG. 4;

FIG. 7 is a cross-sectional view showing an example of a display panel taken along the line I1 - I1′ of FIG. 5;

FIG. 8 is a cross-sectional view showing another example of a display panel taken along the line I1 - I1′ of FIG. 5;

FIG. 9 is a perspective view showing an example of an electronic device;

FIG. 10 is an exploded perspective view for illustrating the electronic device of FIG. 9;

FIG. 11 is a perspective view showing another example of an electronic device;

FIG. 12 is a view showing a deposition apparatus according to some embodiments of the present disclosure;

FIG. 13 is a bottom view showing the backplane substrate shown in FIG. 12;

FIG. 14 is a plan view showing a deposition mask according to some embodiments of the present disclosure;

FIG. 15 is an enlarged plan view showing mask cell areas illustrated in FIG. 14;

FIG. 16 is a cross-sectional view showing an example of a deposition mask cut along the line I2-I2′ of FIG. 15;

FIG. 17 is an enlarged view of the portion A of FIG. 16;

FIG. 18 is a cross-sectional view showing another example of a deposition mask cut along the line I2-I2′ of FIG. 15;

FIG. 19 is an enlarged view of portion B of FIG. 18;

FIG. 20 is a cross-sectional view showing a state in which a deposition mask according to some embodiments of the present disclosure is in contact with a backplane substrate;

FIG. 21 is a block diagram of an electronic device according to some embodiments of the present disclosure; and

FIG. 22 is a view showing electronic devices according to some embodiments of the present disclosure.

### DETAILED DESCRIPTION

Aspects and features of embodiments according to the present disclosure and methods to achieve them will become more apparent from the descriptions of example embodiments hereinbelow with reference to the accompanying drawings. However, embodiments according to the present disclosure are not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be located directly on the element B and/or the element A may be located indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the present disclosure will be described in detail with reference to the accompanying drawings.

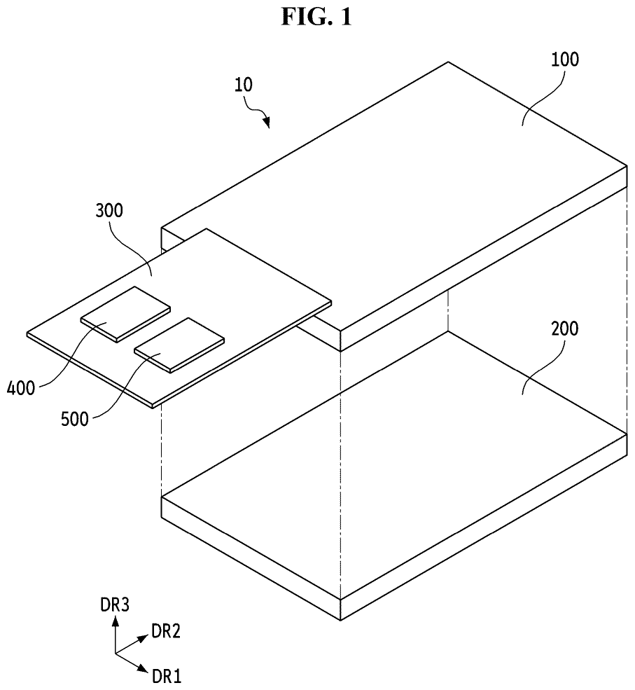

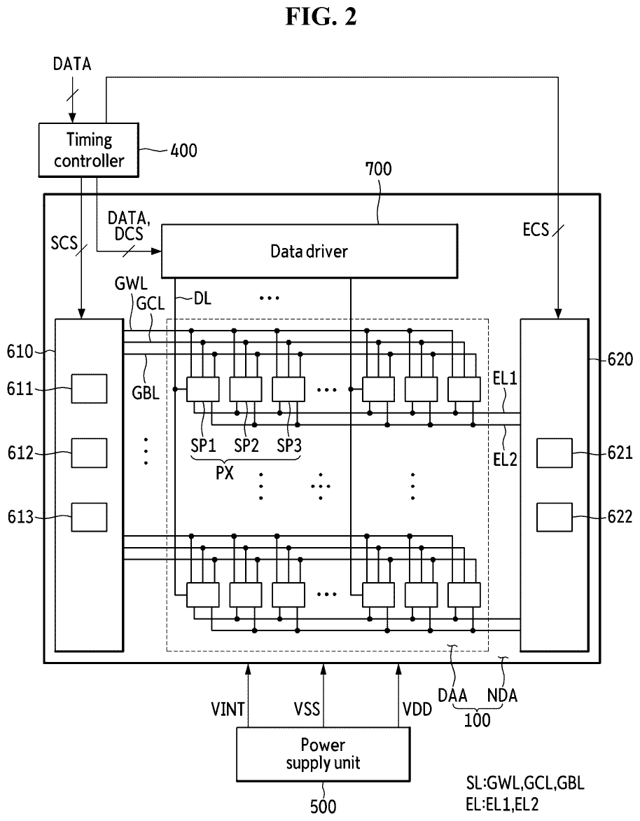

FIG. 1 is an exploded, perspective view showing a display device according to some embodiments of the present disclosure. FIG. 2 is a plan view for illustrating the display device shown in FIG. 1.

Referring to FIGS. 1 and 2, a display device 10 according to some embodiments displays moving images (e.g., video images) or still images (e.g., static images). The display device 10 according to some embodiments may be employed by portable electronic devices such as a mobile phone, a smart phone, a tablet PC, a mobile communications terminal, an electronic notebook, an electronic book, a portable multimedia player (PMP), a navigation device and a ultra mobile PC (UMPC). For example, the display device 10 according to some embodiments of the present disclosure may be used as a display unit of a television, a laptop computer, a monitor, an electronic billboard, or the Internet of Things (IOT). Alternatively, the display device 10 according to some embodiments of the present disclosure may be applied to a smart watch, a watch phone, or a head-mounted display (HMD) for implementing virtual reality and augmented reality.

According to some embodiments, the display device 10 includes a display panel 100, a heat dissipation layer 200, a circuit board 300, a timing control circuit 400, and a power supply circuit 500.

The display panel 100 may have a shape similarly to a rectangular shape when viewed from the top (e.g., in a plan view). For example, the display panel 100 may have a shape similar to a rectangle having shorter sides in a first direction DR1 and longer sides in a second direction DR2 intersecting the first direction DR1 when viewed from the top (e.g., in a plan view). In the display panel 100, the corners where the shorter sides in the first direction DR1 meet the longer sides in the second direction DR2 may be rounded with a predetermined curvature or may be a right angle. The shape of the display panel 100 when viewed from the top (e.g., in a plan view) is not limited to a rectangular shape, but may be formed in a shape similar to other polygonal shapes, a circular shape, or an elliptical shape. The shape of the display device 10 may follow the shape of the display panel 100 when viewed from the top (e.g., in a plan view), but the embodiments of the present disclosure are not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA where images are displayed, and a non-display area NDA where no images are displayed as shown in FIG. 2.

The plurality of pixels PX may be located in the display area DAA. The pixels PX may be arranged in a matrix in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL includes a plurality of first emission control lines ECL1 and a plurality of second emission control lines ECL2.

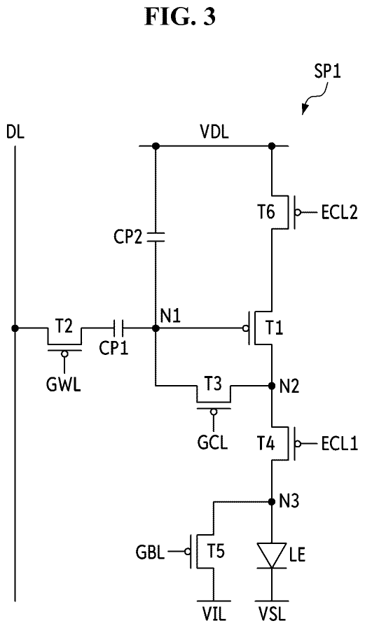

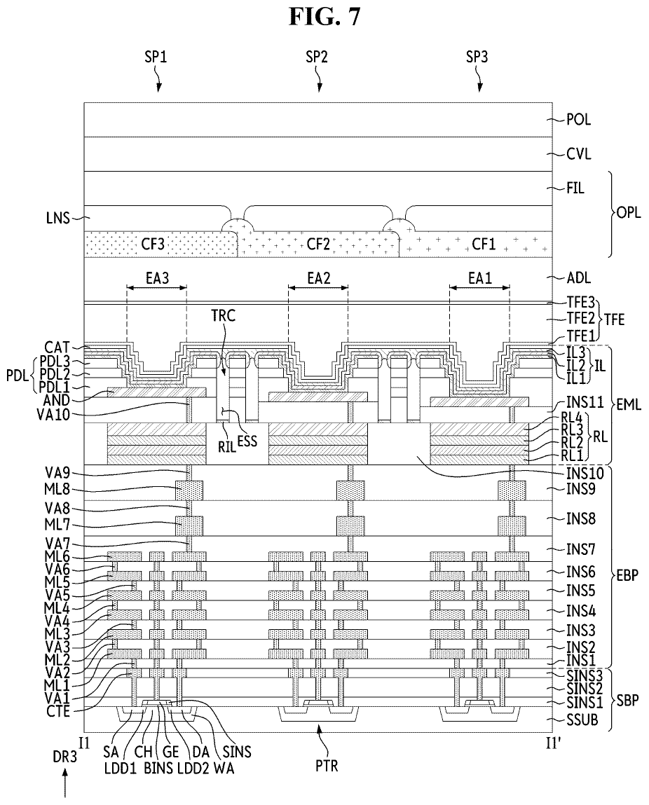

The plurality of pixels PX includes a plurality of sub-pixels SP1, SP2 and SP3. The plurality of sub-pixels SP1, SP2 and SP3 includes a plurality of pixel transistors as shown in FIG. 3. The pixel transistors are formed via a semiconductor process and may be located on a semiconductor substrate SSUB (see FIG. 7). For example, the pixel transistors of a data driver 700 may be implemented as complementary metal oxide semiconductor (CMOS). It should be understood, however, that the embodiments of the present disclosure are not limited thereto.

Each of the plurality of sub-pixels SP1, SP2 and SP3 may be connected to one write scan line GWL, one control scan line GCL, one bias scan line GBL, one first emission control line ECL1, one second emission control line ECL2, and one data line DL. Each of the sub-pixels SP1, SP2 and SP3 may receive the data voltage from the data line DL according to the write scan signal from the write scan line GWL, and may allow the light-emitting elements to emit light according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors. A plurality of scan transistors and a plurality of light-emitting transistors are formed via a semiconductor process and may be formed on the semiconductor substrate SSUB (see FIG. 7). For example, a plurality of scan transistors and a plurality of light-emitting transistors may be formed of CMOS. It should be understood, however, that the embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612 and the bias scan signal output unit 613 may receive a scan timing control signal SCS from a timing control circuit 400. The write scan signal output unit 611 may generate write scan signals according to the scan timing control signal SCS from the timing control circuit 400 and sequentially output them to the write scan lines GWL. The control scan signal output unit 612 may generate control scan signals according to the scan timing control signal SCS and sequentially output them to the control scan lines GCL. The bias scan signal output unit 613 may generate bias scan signals according to the scan timing control signal SCS and sequentially output them to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed via a semiconductor process and may be formed on the semiconductor substrate SSUB (see FIG. 7). For example, a plurality of data transistors may be formed of CMOS transistors. It should be understood, however, that the embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs them to the data lines DL. In doing so, the sub-pixels SP1, SP2 and SP3 are selected by the write scan signal of the scan driver 610, and data voltages may be applied to the selected sub-pixels SP1, SP2 and SP3.

The heat dissipation layer 200 may overlap with the display panel 100 in the third direction DR3, which is the thickness direction of the display panel 100. The heat dissipation layer 200 may be located on one surface of the display panel 100, e.g., on the rear surface. The heat dissipation layer 200 serves to release heat generated in the display panel 100. The heat dissipation layer 200 may include a metal layer such as graphite, silver (Ag), copper (Cu), and aluminum (Al) having a high thermal conductivity.

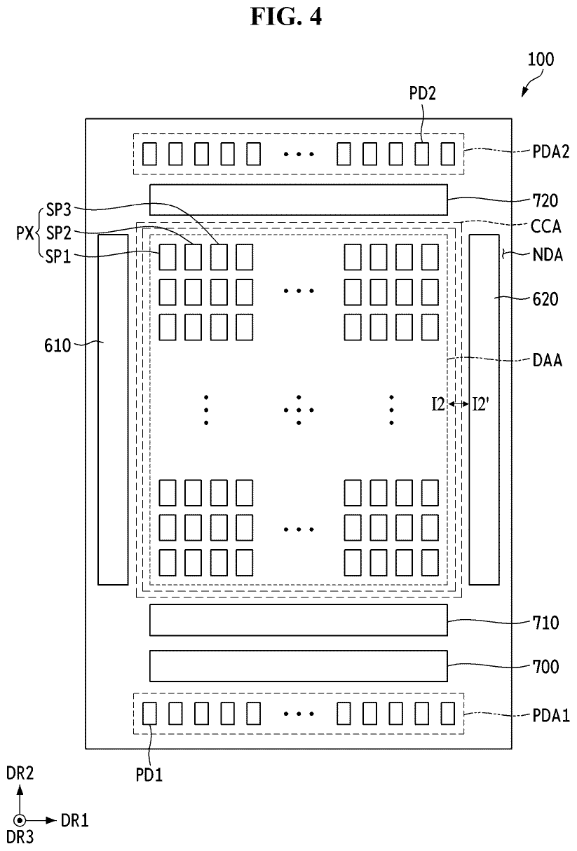

The circuit board 300 may be electrically connected to a plurality of first pads PD1 (see FIG. 4) of a first pad area PDA1 (see FIG. 4) of the display panel 100 using a conductive adhesive member such as an anisotropic conductive film. The circuit board 300 may be a flexible printed circuit board made of a flexible material, or a flexible film. Although the circuit board 300 is unfolded in the example shown in FIG. 1, the circuit board 300 may be bent. When the circuit board 300 is bent, one end of the circuit board 300 may be located on the rear surface of the display panel 100 and/or the rear surface of the heat dissipation layer 200. The other end of the circuit board 300 may be connected to a plurality of first pads PD1 (see FIG. 4) of the first pad area PDA1 (see FIG. 4) of the display panel 100 using a conductive adhesive material. One end of the circuit board 300 may be opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

A power supply circuit 500 may generate a plurality of panel driving voltages in response to a supply power voltage from the outside. For example, the power supply circuit 500 may generate a first driving voltage VSS, a second driving voltage VDD, and a third driving voltage VINT to apply them to the display panel 100. The first driving voltage VSS, the second driving voltage VDD and the third driving voltage VINT will be described later with reference to FIG. 3.

Each of the timing control circuit 400 and the power supply circuit 500 may be implemented as an integrated circuit (IC) and attached to a surface of the circuit board 300. The scan timing control signal SCS, the emission timing control signal ECS, the digital video data DATA and the data timing control signal DCS from the timing control circuit 400 may be supplied to the display panel 100 through the circuit board 300. The first driving voltage VSS, the second driving voltage VDD and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620 and the data driver 700. In this instance, the timing control circuit 400 may include a plurality of timing transistors, and each power supply circuit 500 may include a plurality of power transistors. A plurality of timing transistors and a plurality of power transistors may be formed through a semiconductor process and may be formed on the semiconductor substrate SSUB (see FIG. 7). For example, the plurality of timing transistors and the plurality of power transistors may be formed of CMOS transistors. It should be understood, however, that the embodiments of the present disclosure are not limited thereto. Each of the timing control circuit 400 and the power supply circuit 500 may be located between the data driver 700 and the first pad area PDA1 (see FIG. 4).

FIG. 3 is an equivalent circuit diagram showing an example of the first sub-pixel shown in FIG. 2. Although FIG. 3 illustrates various components in a sub-pixel according to some embodiments, embodiments according to the present disclosure are not limited thereto, and according to some embodiments, the sub-pixel may include additional components or fewer components without departing from the spirit and scope of embodiments according to the present disclosure.

Referring to FIG. 3, a first sub-pixel SP1 may be connected to a write scan line GWL, a control scan line GCL, a bias scan line GBL, a first emission control line ECL1, a second emission control line ECL2 and a data line DL. In addition, the first sub-pixel SP1 may be connected to a first driving voltage line VSL where the first driving voltage VSS equal to a low-level voltage is applied, a second driving voltage line VDL where the second driving voltage VDD equal to a high-level voltage is applied, and a third driving voltage line VIL where the third driving voltage VINT equal to an initialization voltage is applied.

The first sub-pixel SP1 includes a plurality of transistors T1 to T6, a light-emitting element LE, a first capacitor CP1, and a second capacitor CP2.

The light-emitting element LE emits light according to a driving current Ids flowing in a channel of the first transistor T1. The amount of the light emitted from the light-emitting element LE may be proportional to the driving current Ids. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode. It should be understood, however, that the present disclosure is not limited thereto. For example, the light-emitting element LE may be an inorganic light-emitting element including a first electrode, a second electrode, and an inorganic semiconductor located between the first electrode and the second electrode. In this instance, the light-emitting element LE may be a micro light-emitting diode.

The first transistor T1 may be a driving transistor for controlling the source-drain current Ids (hereinafter referred to as “driving current”) flowing between the source electrode and the drain electrode according to the voltage applied to the gate electrode.

The second transistor T2 may be located between one electrode of the first capacitor CP1 and the data line DL. The second transistor T2 is turned on by a write scan signal from the write scan line GWL and connects one electrode of the first capacitor CP1 to the data line DL. Accordingly, the data voltage of the data line DL may be applied to one electrode of the first capacitor CP1.

A third transistor T3 may be connected between a first node N1 and a second node N2. The third transistor T3 is turned on by the write control signal of the write control line GCL and connects the first node N1 to the second node N2. Accordingly, if the gate electrode and source electrode of the first transistor T1 are connected with each other, the first transistor T1 may act like a diode.

The fourth transistor T4 may be connected between the second node N2 and a third node N3. The fourth transistor T4 is turned on by a first emission control signal of the first emission control line ECL1 and connects the second node N2 to the third node N3. Accordingly, the driving current of the first transistor T1 may be supplied to the light-emitting element LE. The fifth transistor T5 may be located between the third node N3 and the third driving voltage line VIL. The fifth transistor T5 is turned on by a bias scan signal of the bias scan line GBL and connects the third node N3 to the third driving voltage line VIL. Accordingly, the third driving voltage VINT of the third driving voltage line VIL may be applied to the first electrode of the light-emitting element LE.

The sixth transistor T6 may be located between the source electrode of the first transistor T1 and the second supply voltage line VDL. The sixth transistor T6 is turned on by the second emission control signal of the second emission control line ECL2 and connects the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be, but is not limited to, a p-type MOSFET. Each of the first to sixth transistors T1 to T6 may be an n-type MOSFET. Alternatively, some of the first to sixth transistors T1 to T6 may be p-type MOSFETs, and the other transistors may be n-type MOSFETs.

Although the first sub-pixel SP1 includes the six transistors T1 to T6 and the two capacitors C1 and C2 in the example shown in FIG. 3, it should be noted that the equivalent circuit diagram of the first sub-pixel SP1 is not limited to that shown in FIG. 3. For example, the numbers of the transistors and the capacitors of the first sub-pixel SP1 are not limited to those shown in FIG. 3.

In addition, the equivalent circuit diagram of the second sub-pixel SP2 and the equivalent circuit diagram of the third sub-pixel SP3 may be substantially identical to the equivalent circuit diagram of the first sub-pixel SP1 described above with reference to FIG. 3; and, therefore, some redundant descriptions may be omitted.

FIG. 4 is a plan view showing an example of the display panel shown in FIG. 1.

Referring to FIG. 4, the display area DAA of the display panel 100 according to some embodiments includes a plurality of pixels PX arranged in a matrix configuration. The non-display area NDA of the display panel 100 according to some embodiments includes the scan driver 610, the emission driver 620, the data driver 700, a first distribution circuit 710, a second distribution circuit 720, a first pad area PDA1, and a second pad area PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the opposite side of the display area DAA in the first direction DR1. It should be understood, however, that the embodiments of the present disclosure are not limited thereto. The scan driver 610 and the emission driver 620 may be located on both the first and second sides of the display area DAA.

The first pad area PDA1 may include a plurality of first pads PD1 connected to pads or bumps of the circuit board 300 through a conductive adhesive member. The first pad area PDA1 may be located on a third side of the display area DAA. For example, the first pad area PDA1 may be located on one side of the display area DAA in the second direction DR2. The first pad area PDA1 may be located on the outer side of the data driver 700 in the second direction DR2.

The second pad area PDA2 may include a plurality of second pads PD2 which are inspection pads for testing whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad area PDA2 may be located on a fourth side of the display area DAA. For example, the second pad area PDA2 may be located on the opposite side of the display area DAA in the second direction DR2. The second pad area PDA2 may be located on the outer side of the second distribution circuit 700 in the second direction DR2.

The first distribution circuit 710 distributes data voltages applied via the first pad area PDA1 to a plurality of data lines DL. For example, the first distribution circuit 710 may divide the data voltages applied via one first pad PD1 of the first pad area PDA1 into P data lines DL, thereby reducing the number of the plurality of first pads PD1, where P is a positive integer equal to or greater than two. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad area PDA2 to the scan driver 610, the emission driver 620, and the data lines DL. The second pad area PDA2 and the second distribution circuit 720 may be elements to test the operation of each of the pixels PX in the display area DAA. The second distribution circuit 720 may be located on a fourth side of the display area DAA of the display panel 100. For example, the second distribution circuit 720 may be located on the opposite side of the display area DAA in the second direction DR2.

In a cathode connection area CCA, a second electrode CAT (see FIG. 7) of a display element layer EML (see FIG. 7) may be connected to the first driving voltage line VSL in the non-display area NDA. The cathode connection area CCA may be located on at least one outer side of the display area DAA. For example, the cathode connection area CCA may be located on the outer side of at least one of the left side, the right side, the upper side and the lower side of the display area DAA. Alternatively, the cathode connection area CCA may be located to surround the display area DAA as shown in FIG. 4 in order to reduce deviations of the first driving voltage VSS due to a voltage drop (IR drop) or a voltage rise (IR rising) of the second electrode CAT in the display area DAA.

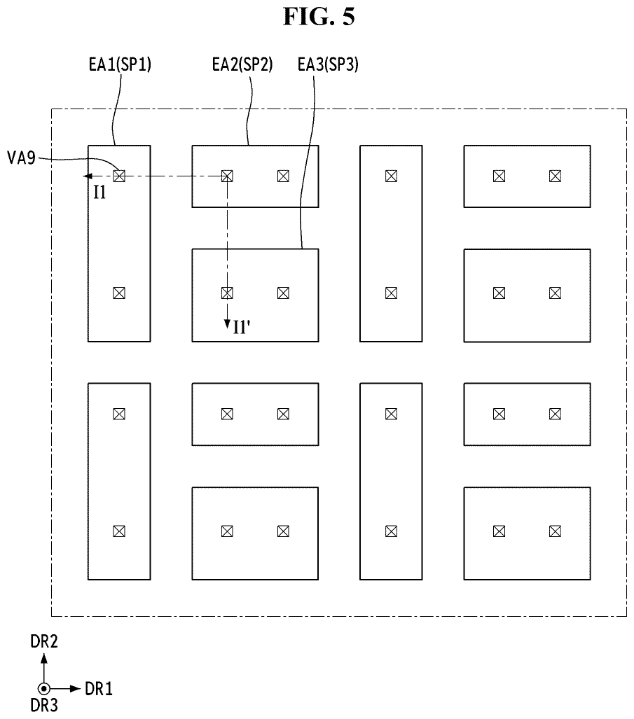

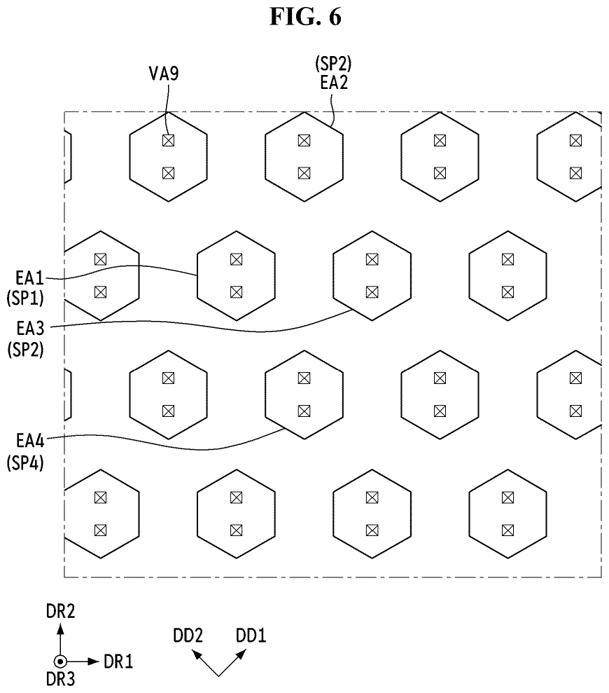

FIG. 5 is an enlarged plan view showing an example of the display area of FIG. 4. FIG. 6 is an enlarged plan view showing another example of the display area of FIG. 4.

Referring to FIGS. 5 and 6, each of the plurality of pixels PX includes a first emission area EA1 that is the emission area of the first sub-pixel SP1, a second emission area EA2 that is the emission area of the second sub-pixel SP2, and a third emission area EA3 that is the emission area of the third sub-pixel SP3.

The first emission area EA1, the second emission area EA2 and the third emission area EA3 may have a rectangular shape or a hexagonal shape as shown in FIGS. 5 and 6 when viewed from the top (e.g., in a plan view). It should be understood, however, that the embodiments of the present disclosure are not limited thereto. The first emission area EA1, the second emission area EA2 and the third emission area EA3 may have a polygonal shape other than a rectangle or a hexagon, a circular shape, an elliptical shape or an irregular shape when viewed from the top (e.g., in a plan view).

As shown in FIG. 5, in each of the plurality of pixels PX, the first emission area EA1 and the second emission area EA2 may be adjacent to each other in the first direction DR1. In addition, the first emission area EA1 and the third emission area EA3 may be adjacent to each other in the first direction DR1. In addition, the second emission area EA2 and the third emission area EA3 may be adjacent to each other in the second direction DR2. The first emission area EA1, the second emission area EA2 and the third emission area EA3 may have different areas.

Alternatively, as shown in FIG. 6, emission areas EA1, EA2, EA3 and EA4 may have a hexagonal shape when viewed from the top (e.g., in a plan view). In this instance, the first emission area EA1 and the third emission area EA3 may be adjacent to each other in the first direction DR1, and the second emission area EA2 and the fourth emission area EA4 may be adjacent to each other in the second direction DR2. In addition, the first emission area EA1 and the second emission area EA2 may be adjacent to each other in a first diagonal direction DD1, and the second emission area EA2 and the third emission area EA3 may be adjacent to each other in a second diagonal direction DD2. In addition, the first emission area EA1 and the fourth emission area EA4 may be adjacent to each other in the second diagonal direction DD2, and the third emission area EA3 and the fourth emission area EA4 may be adjacent to each other in the first diagonal direction DD1. The first diagonal direction DD1 refer to a direction between the first direction DR1 and the second direction DR2, and refers to a direction inclined by 45 degrees relative to the first direction DR1 and the second direction DR2. The second diagonal direction DD2 may be orthogonal to the first diagonal direction DD1.

The first sub-pixel SP1 may output first light, the second sub-pixel SP2 may output second light, and the third sub-pixel SP3 may output third light. The first light may be light of a blue wavelength band, the second light may be light of a green wavelength band, and the third light may be light of a red wavelength band. For example, the blue wavelength band may refer that the main peak wavelength of light lies in the wavelength band of approximately 370 nm to 460 nm, the green wavelength band may refer that the main peak wavelength of light lies in the wavelength band of approximately 480 nm to 560 nm, and the red wavelength band may refer to that the main peak wavelength of light lies in the wavelength band of approximately 600 nm to 750 nm.

Each of the plurality of pixels PX may include three emission areas EA1, EA2 and EA3 as shown in FIG. 5, or may include four emission areas EA1, EA2, EA3 and EA4 as shown in FIG. 6. In this instance, the fourth emission area EA4 may output the same second light as the second emission area EA2. It should be understood, however, that the embodiments of the present disclosure are not limited thereto.

The emission areas of the plurality of pixels PX may have a stripe pattern in which the emission areas are arranged in the first direction DR1, a PenTile® matrix in which the emission areas are arranged in a diamond pattern as shown in FIG. 6, or a hexagonal structure in which the emission areas are arranged in a hexagonal pattern.

FIG. 7 is a cross-sectional view showing an example of a display panel taken along the line I1 - I1′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively. The plurality of pixel transistors PTR may be the first to sixth transistors T1 to T6 described above with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be located in the upper surface of the semiconductor substrate SSUB. The well areas WA may be doped with second-type impurities. The second-type impurities may be different from the first-type impurities. For example, when the first-type impurities are p-type impurities, the second-type impurities may be n-type impurities. Alternatively, when the first-type impurities are n-type impurities, the second-type impurities may be p-type impurities.

Each of the well areas WA includes a source region SA associated with a source electrode of a pixel transistor PTR, a drain region DA associated with a drain electrode thereof, and a channel region CH between the source region SA and the drain region DA.

A bottom insulating film BINS may be located between the gate electrode GE and the well area WA. Side insulating film SINS may be located on the side surfaces of the gate electrode GE. The side insulating film SINS may be located on the bottom insulating film BINS.

Each of the source region SA and the drain region DA may be doped with the first-type impurities. The gate electrode GE of the pixel transistor PTR may overlap with the well area WA in the third direction DR3 which is the thickness direction of the semiconductor substrate SSUB. The channel region CH may overlap with the gate electrode GE in the third direction DR3. The source region SA may be located on one side of the gate electrode GE, and the drain region DA may be located on the opposite side of the gate electrode GE.

Each of the plurality of well areas WA may further include a first low-concentration impurity region LDD1 located between the channel region CH and the source region SA, and a second low-concentration impurity region LDD2 located between the channel region CH and the drain region DA. The first low-concentration impurity region LDD1 may have a lower impurity concentration than the source region SA due to the bottom insulating film BINS. The second low-concentration impurity region LDD2 may have a lower impurity concentration than the drain region DA due to the bottom insulating film BINS. The distance between the source region SA and the drain region DA may be increased by the first low-concentration impurity region LDD1 and the second low-concentration impurity region LDD2. Accordingly, the length of the channel region CH of each of the pixel transistors PTR may be increased.

A first semiconductor insulating film SINS1 may be located on the semiconductor substrate SSUB. A second semiconductor insulating film SINS2 may be located on the first semiconductor insulating film SINS1.

A plurality of contact terminals CTE may be located on the second semiconductor insulating film SINS2. Each of the plurality of contact terminals CTE may be connected to one of the gate electrode GE, the source region SA and the drain region DA of each of the pixel transistors PTR through a hole penetrating the first semiconductor insulating film SINS1 and the second semiconductor insulating film INS2. The contact terminals CTE may be made of one of copper (Cu), aluminum (Al), tungsten (W), molybdenum (Mo), chromium (Cr), gold (Au), titanium (Ti), nickel (Ni) and neodymium (Nd), or an alloy containing any one of them.

A third semiconductor insulating film SINS3 may be located on the side surface of each of the contact terminals CTE. The upper surface of each of the contact terminals CTE may not be covered by the third semiconductor insulating film SINS3 but may be exposed.

Each of the first semiconductor insulating film SINS1, the second semiconductor insulating film SINS2 and the third semiconductor insulating film SINS3 may be formed of, but is not limited to, a silicon carbon nitride (SiCN) or silicon oxide (SiOx)-based inorganic film.

The semiconductor substrate SSUB may be replaced with a glass substrate or a polymer resin substrate such as polyimide. In this instance, thin-film transistors may be located on a glass substrate or a polymer resin substrate. The glass substrate may be a rigid substrate that is not bent, while the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS11. In addition, the light-emitting element backplane EBP includes a plurality of insulating films INS1 to INS9 located between the first to eighth conductive layers ML1 to ML8.

The first to eighth insulating films INS1 to INS8 may insulate the first to eighth conductive layers ML1 to ML8. The first to eighth conductive layers ML1 to ML8 may implement a circuit of a first sub-pixel SP1 shown in FIG. 4 by connecting a plurality of contact terminals CTE exposed from the semiconductor backplane SBP.

For example, the first to sixth transistors T1 to T6 are only formed in the semiconductor backplane SBP, and the connection of the first to sixth transistors T1 to T6 and the first capacitor C1 and the second capacitor C2 are made through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also made through the first to eighth conductive layers ML1 to ML8.

The first to eighth conductive layers ML1 to ML8 and the first to eighth vias VA1 to VA8 may be made of substantially the same material. The first to eighth conductive layers ML1 to ML8 and the first to eighth vias VA1 to VA8 may be made of one of copper (Cu), aluminum (Al), tungsten (W), molybdenum (Mo), chromium (Cr), gold (Au), titanium (Ti), nickel (Ni) and neodymium (Nd), or an alloy containing any one of them. The first to eighth vias VA1 to VA8 may be made of substantially the same material. The first to eighth insulating films INS1 to INS8 may be formed of a silicon oxide (SiOx)-based inorganic film, but embodiments of the present specification are not limited thereto.

The ninth insulating film INS9 may be located over the eighth insulating film INS8 and the eighth conductive layer ML8. The ninth insulating film INS9 may be formed of a silicon oxide (SiOx)-based inorganic film, but the embodiments of the present disclosure are not limited thereto.

Each of the ninth vias VA9 may penetrate through the ninth insulating film INS9 to be connected to the exposed eighth conductive layer ML8. The ninth vias VA9 may be made of one of copper (Cu), aluminum (Al), tungsten (W), molybdenum (Mo), chromium (Cr), gold (Au), titanium (Ti), nickel (Ni) and neodymium (Nd), or an alloy containing any one of them.

The display element layer EML may be located on the light-emitting element backplane EBP. The display element layer EML may include tenth and eleventh insulating films INS10 and INS11, reflective electrodes RL, first electrodes AND, a light-emitting stack IL, a second electrode CAT, a pixel-defining layer PDL, and a plurality of trenches TRC.

The reflective electrodes RL may be located on the ninth insulating film INS9. The reflective electrodes RL may include one or more reflective electrodes RL1, RL2, RL3 and RL4. For example, the reflective electrodes RL may include first to fourth reflective electrodes RL1, RL2, RL3 and RL4 as shown in FIG. 7.

The first reflective electrodes RL1 may be located on the ninth insulating film INS9 and may be connected to the ninth via VA9. The second reflective electrodes RL2 may be located on the first reflective electrodes RL1, respectively. The third reflective electrodes RL3 may be located on the second reflective electrodes RL2, respectively. The fourth reflective electrodes RL4 may be located on the third reflective electrodes RL3, respectively.

Because the second reflective electrode RL2 is an electrode that substantially reflects light from the light-emitting elements LE, the thickness of the second reflective electrode RL2 may be greater than the thickness of the first reflective electrode RL1, the thickness of the third reflective electrode RL3 and the thickness of the fourth reflective electrode RL4.

The first reflective electrodes RL1 may be made of one of copper (Cu), aluminum (Al), tungsten (W), molybdenum (Mo), chromium (Cr), gold (Au), titanium (Ti), nickel (Ni) and neodymium (Nd), or an alloy containing any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

A tenth insulating film INS10 may be located on the ninth insulating film INS9. The tenth insulating film INS10 may be located between the reflective electrodes RL that are adjacent to each other. The tenth insulating film INS10 may be a film for providing flat surfaces to the reflective electrodes RL. An eleventh insulating film INS11 may be located on the tenth insulating film INS10 and the reflective electrode RL.

The tenth insulating film INS10 and the eleventh insulating film INS11 may be formed of a silicon oxide (SiOx)-based inorganic film, but the embodiments of the present disclosure are not limited thereto.

The eleventh insulating film INS11 may be an optical auxiliary layer for adjusting the resonance distance of light output from the light-emitting stack IL in at least one sub-pixel among the first sub-pixel SP1, the second sub-pixel SP2 and the third sub-pixel SP3. The thickness of the eleventh insulating film INS11 may be different in the first sub-pixel SP1, the second sub-pixel SP2 and the third sub-pixel SP3. For example, in order to adjust the distance from the reflective electrode RL to the second electrode CAT according to the main wavelength of light emitted from each of the first sub-pixel SP1, the second sub-pixel SP2 and the third sub-pixel SP3, the thickness of the eleventh insulating film INS11 may be determined in each of the first sub-pixel SP1, the second sub-pixel SP2 and the third sub-pixel SP3.

For example, as shown in FIG. 7, the thickness of the eleventh insulating film INS11 in the first sub-pixel SP1 may be greater than the thickness of the eleventh insulating film INS11 in the second sub-pixel SP2, and the thickness of the eleventh insulating film INS11 in the second sub-pixel SP2 may be greater than the thickness of the eleventh insulating film INS11 in the third sub-pixel SP3. In this instance, the distance between the first electrode AND and the reflective electrode RL in the first sub-pixel SP1 may be greater than the distance between the first electrode AND and the reflective electrode RL in the second sub-pixel SP2. In addition, the distance between the first electrode AND and the reflective electrode RL in the second sub-pixel SP2 may be greater than the distance between the first electrode AND and the reflective electrode RL in the third sub-pixel SP3.

The tenth vias VA10 may penetrate through the eleventh insulating film INS11 to be connected to the exposed fourth reflective electrodes RL4, respectively. The tenth vias VA10 may be made of one of copper (Cu), aluminum (Al), tungsten (W), molybdenum (Mo), chromium (Cr), gold (Au), titanium (Ti), nickel (Ni) and neodymium (Nd), or an alloy containing any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be located on the eleventh insulating film INS11 and may be connected to the tenth via VA10. The first electrode AND of each of the light-emitting elements LE may be connected to the drain region DA or the source region SA of the pixel transistor PTR through the tenth via VA10, the reflective electrodes RL, the first to ninth vias VA1 to VA9, the first to eighth metal layers ML1 to ML8 and the contact terminals CTE. The first electrode AND of each of the light-emitting elements LE may be made of one of copper (Cu), aluminum (Al), tungsten (W), molybdenum (Mo), chromium (Cr), gold (Au), titanium (Ti), nickel (Ni) and neodymium (Nd), or an alloy containing any one of them. For example, the first electrode AND of each of the light-emitting elements LE may be titanium nitride (TiN).

The pixel-defining layer PDL may be located partially on the first electrode AND of each of the light-emitting elements LE. The pixel-defining layer PDL may cover the edge of the first electrode AND of each of the light-emitting elements LE. The pixel-defining layer PDL may define the first emission areas EA1, the second emission areas EA2, and the third emission areas EA3. In each of the first emission area EA1, the second emission area EA2 and the third emission area EA3, a light-emitting element LE including a first electrode AND, a light-emitting stack IL, and a second electrode CAT are located.

A first emission area EA1 may be defined as an area in the first sub-pixel SP1 where the first electrode AND, the light-emitting stack IL and the second electrode CAT are sequentially stacked on one another to emit light. A second emission area EA2 may be defined as an area in the second sub-pixel SP2 where the first electrode AND, the light-emitting stack IL and the second electrode CAT are sequentially stacked on one another to emit light. A third emission area EA3 may be defined as an area in the third sub-pixel SP3 where the first electrode AND, the light-emitting stack IL and the second electrode CAT are sequentially stacked on one another to emit light.

The pixel-defining layer PDL may include first to third pixel-defining films PDL1, PDL2 and PDL3. The first pixel-defining layer PDL1 may be located on the edge of the first electrode AND of each of the light-emitting elements LE, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2 and the third pixel-defining layer PDL3 may be formed of a silicon oxide (SiOx)-based inorganic film. Alternatively, the first pixel-defining layer PDL1 and the third pixel-defining layer PDL3 may be formed of a silicon nitride (SiNx)-based inorganic film, and the second pixel-defining layer PDL2 may be formed of silicon oxide (SiOx)-based inorganic film. The thickness of the first pixel-defining layer PDL1, the second pixel-defining layer PDL2, and the third pixel-defining layer PDL3 may each be approximately 500 Å.

In order to prevent or reduce instances of the first inorganic encapsulation film TFE1 breaking due to step coverage, the first pixel-defining layer PDL1, the second pixel-defining layer PDL2 and the third pixel-defining layer PDL3 may have a cross-sectional structure in the form of stairs. Herein, the step coverage refers to a ratio of a thin film applied on an inclined portion to the thin film applied on a flat portion. The lower the step coverage is, the more likely it is that the thin film would break at the inclined portion.

Each of the plurality of trenches TRC may penetrate the first pixel-defining layer PDL1, the second pixel-defining layer PDL2, and the third pixel-defining layer PDL3. At least a portion of the eleventh insulating film INS11 may be partially recessed at each of the plurality of trenches TRC.

At least one trench TRC may be formed between the adjacent ones of the sub-pixels SP1, SP2, and SP3. Although two trenches TRC are formed between adjacent ones of the pixels SP1, SP2, and SP3 in the example shown in FIG. 7, the embodiments of the present disclosure are not limited thereto.

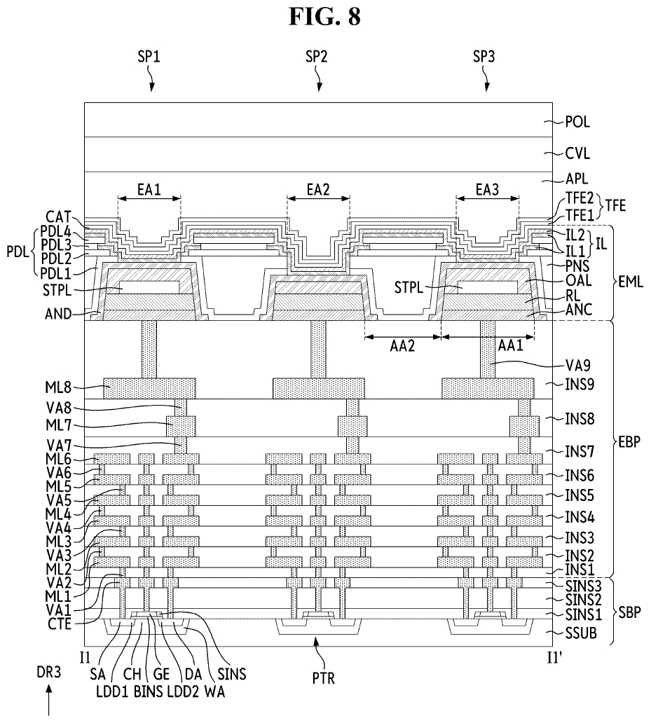

The light-emitting stack IL may include a plurality of stacks IL1, IL2, and IL3. Although the light-emitting stack IL has a three-tandem structure including a first stack layer IL1, a second stack layer IL2, and a third stack layer IL3 in the example shown in FIG. 7, the embodiments of the present disclosure are not limited thereto. For example, the light-emitting stack IL may have a two-tandem structure including two stack layers as shown in FIG. 8.

In a three-tandem structure, the light-emitting stack IL may have a tandem structure including a plurality of intermediate layers IL1, IL, and IL3 emitting different lights. For example, the light-emitting stack IL may include the first stack layer IL1 that outputs the first light, the second stack layer IL2 that outputs the second light, and the third stack layer IL3 that outputs the third light. The first stack layer IL1, the second stack layer IL2 and the third stack layer IL3 may be sequentially stacked on one another.

The first stack layer IL1 may have a structure in which a first hole transport layer, a first emissive layer that emits the first light, and a first electron transport layer are sequentially stacked on one another. The second stack layer IL2 may have a structure in which a second hole transport layer, a second emissive layer that emits the second light, and a second electron transport layer are sequentially stacked on one another. The third stack layer IL3 may have a structure in which a third hole transport layer, a third emissive layer that emits the third light, and a third electron transport layer are sequentially stacked on one another.

A first charge generation layer may be located between the first stack layer IL1 and the second stack layer IL2 to supply charges to the second stack layer IL2 and electrons to the first stack layer IL1. The first charge generation layer may include an n-type charge generation layer that supplies electrons to the first stack layer IL1, and a p-type charge generation layer that supplies holes to the second stack layer IL2. The n-type charge generation layer may include a dopant of a metallic material.

A second charge generation layer may be located between the second stack layer IL2 and the third stack layer IL3 to supply charges to the third stack layer IL3 and electrons to the second stack layer IL2. The second charge generation layer may include an n-type charge generation layer that supplies electrons to the second stack layer IL2, and a p-type charge generation layer that supplies holes to the third stack layer IL3.

The first stack layer IL1 may be located on the first electrodes AND and the pixel-defining layer PDL. In each of the trenches TRC, a residual film RIL located on the bottom of the trench TRC may be made of the same material as the first stack layer IL1. Due to the trenches TRC, the first stack layer IL1 may be disconnected between the adjacent sub-pixels SP1, SP2, and SP3. The second stack layer IL2 may be located on the first stack layer IL1. Due to the trenches TRC, the second stack layer IL2 may be disconnected between the adjacent sub-pixels SP1, SP2, and SP3. In the trenches TRC, a cavity ESS or empty space may be located between the residual film IL and the second stack layer IL2. The third stack layer IL3 may be located on the second stack layer IL2. The third stack layer IL3 may not be disconnected by the trenches TRC and may be arranged to cover the second stack layer IL2 in each of the trenches TRC.

In the three-tandem structure, each of the plurality of trenches TRC may be a feature that disconnects the first to third hole transport layers, the first charge generation layer and the second charge generation layer of the first to third stack layers IL1, IL2, and IL3 of the display element layer EML between the adjacent sub-pixels SP1, SP2, and SP3. In addition, in the two-tandem structure, each of the plurality of trenches TRC may be a structure that disconnects a charge generation layer and a lower stack layer located between the lower stack layer and an upper stack layer.

In order to stably disconnect the first and second stack layers IL1 and IL2 of the display element layer EML between the adjacent sub-pixels SP1, SP2, and SP3, the height of each of the plurality of trenches TRC may be greater than the height of the pixel-defining layer PDL. The height of each of the plurality of trenches TRC refers to the length measured in the third direction DR3. The height of the pixel-defining layer PDL refer to the length of the pixel-defining layer PDL in the third direction DR3. In order to disconnect the hole transparent layers and the charge generation layers of the light-emitting stack IL of the display element layer EML between the adjacent sub-pixels SP1, SP2, and SP3, there may be other features than the trenches TRC. For example, instead of the trenches TRC, partition walls in the form of an inverse taper may be located on the pixel-defining layer PDL.

In addition, although the light-emitting stack IL that emits light is located in all of the first emission area EA1, the second emission area EA2 and the third emission area EA3 in the example shown in FIG. 7, the embodiments of the present disclosure are not limited thereto. For example, the first emissive layer may be located in the first emission area EA1 but not in the second emission area EA2 or the third emission area EA3, instead of the light-emitting stack IL. In addition, the second emissive layer may be located in the second emission area EA2 but not in the first emission area EA1 or the third emission area EA3. In addition, the third emissive layer may be located in the third emission area EA3 but not in the first emission area EA1 or the second emission area EA2. In this instance, the first to third color filters CF1, CF2, and CF3 of the optical layer OPL may be eliminated.

The second electrode CAT may be located on the light-emitting stack IL. The second electrode CAT may be located on the third stack layer IL3 in each of a plurality of trenches TRC. The second electrode CAT may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the second electrode CAT is formed of a semi-transmissive conductive material, the light extraction efficiency can be increased by using microcavities in each of the first to third sub-pixels SP1, SP2, and SP3.

The encapsulation layer TFE may be located on the display element layer EML. The encapsulation layer TFE may include one or more inorganic films TFE1 and TFE3 to prevent or reduce permeation of contaminants such as oxygen or moisture into the display element layer EML. For example, the first inorganic encapsulation film TFE1 may be located on the second electrode CAT, and the second inorganic encapsulation film TFE3 may be located on the first inorganic encapsulation film TFE1. The first inorganic encapsulation film TFE1 and the second inorganic encapsulation film TFE3 may be made up of multiple layers in which one or more inorganic layers of silicon nitride (SiNx), silicon oxynitride (SiON), silicon oxide (SiOx), titanium oxide (TiOx), and aluminum oxide (AlOx) are alternately stacked on one another.

In addition, the encapsulation layer TFE may include at least one organic film TFE2 in order to protect the display element layer EML from particles such as dust. For example, the organic encapsulation film TFE2 may be located between the first inorganic encapsulation film TFE1 and the second inorganic encapsulation film TFE3. The organic encapsulation film TFE2 may be a monomer. Alternatively, the organic encapsulation film TFE2 may be an organic film such as an acryl resin, an epoxy resin, a phenolic resin, a polyamide resin, a polyimide resin, etc.

An adhesive layer ADL may adhere the encapsulation layer TFE to the optical layer OPL. The adhesive layer ADL may be a double-sided adhesive member. In addition, the adhesive layer ADL may be a transparent adhesive member such as a transparent adhesive and a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the adhesive layer ADL.

The first color filter CF1 may be in line with the first emission area EA1 of the first sub-pixel SP1. The first color filter CF1 may transmit light of the first color, i.e., light in the blue wavelength band. The blue wavelength band may be approximately 370 nm to 460 nm. Therefore, the first color filter CF1 may transmit light of the first color among the lights emitted from the first emission area EA1.

The second color filter CF2 may be in line with the second emission area EA2 of the second sub-pixel SP2. The second color filter CF2 may transmit light of the second color, i.e., light in the green wavelength band. The green wavelength range may be approximately 480 nm to 560 nm. Therefore, the second color filter CF2 may transmit light of the second color among the lights emitted from the second emission area EA2

The third color filter CF3 may be in line with the third emission area EA3 of the third sub-pixel SP3. The third color filter CF3 may transmit light of the third color, i.e., light in the red wavelength band. The blue wavelength band may be approximately 600 nm to 750 nm. Therefore, the third color filter CF3 may transmit light of the third color among the lights emitted from the third emission area EA3.

The lenses LNS may be located on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be located on a plurality of lenses LNS. The filling layer FIL may have a predetermined refractive index so that light travels in the third direction DR3 at the interface between the plurality of lenses LNS and the filling layer FIL. In addition, the filling layer FIL may be a planarization layer. The filling layer FIL may be an organic film such as an acryl resin, an epoxy resin, a phenolic resin, a polyamide resin, and a polyimide resin.

The cover layer CVL may be located on the filling layer FIL. The cover layer CVL may be a glass substrate or a polymer resin such as a resin. If the cover layer CVL is a glass substrate, it may be attached to the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the embodiments of the present disclosure are not limited thereto. However, when visibility degradation caused by reflection of external light is sufficiently overcome by the first to third color filters CF1, CF2, and CF3, the polarizing plate may be omitted.

FIG. 8 is a cross-sectional view showing another example of a display panel taken along the line I1-I1′ of FIG. 5.

The embodiments of FIG. 8 are different from the embodiments of FIG. 7 in that a first electrode AND of each of the light-emitting elements LE is electrically connected to side surfaces of a connection electrode ANC connected to the eighth conductive layer ML8. In addition, the embodiments of FIG. 8 differ from the embodiments of FIG. 7 in that the trenches TRC are eliminated, and instead, a third pixel-defining layer PDL3 and a fourth pixel-defining layer PDL4 have a cross-sectional structure in the shape of an eave or a mushroom. Some redundant description may be omitted.

Referring to FIG. 8, a plurality of connection electrodes ANC may be located on first portions AA1 of the ninth insulating film INS9, respectively. The connection electrodes ANC may be located on the first portions AA1 of the ninth insulating film INS9, respectively. The plurality of connection electrodes ANC may be made of one of copper (Cu), aluminum (Al), tungsten (W), molybdenum (Mo), chromium (Cr), gold (Au), titanium (Ti), nickel (Ni) and neodymium (Nd), an alloy containing any one of them, or transparent conductive oxide. For example, the connection electrodes ANC may include, but is not limited to, titanium (Ti), titanium nitride (TiN), indium tin oxide (ITO), or indium zinc oxide (IZO).

A plurality of reflective electrodes RL may be located on a plurality of connection electrodes ANC, respectively. The reflective electrodes RL may be located on the connection electrodes ANC, respectively. The plurality of reflective electrodes RL may be made of one of copper (Cu), aluminum (Al), tungsten (W), molybdenum (Mo), chromium (Cr), gold (Au), titanium (Ti), nickel (Ni) and neodymium (Nd), or an alloy containing any one of them. For example, each of the plurality of reflective electrodes RL may include aluminum (Al) having high reflectivity.

A plurality of optical auxiliary layers OAL may be located on a plurality of reflective electrodes RL, respectively. The optical auxiliary layers OAL may be located on the reflective electrodes RL, respectively. The optical auxiliary layers OAL may be formed of an inorganic film of silicon oxide (SiOx) or the like, but the embodiments of the present disclosure are not limited thereto.

A step layer STPL may be located on a reflective electrode RL in each of the first emission area EA1 and the third emission area EA3, and an optical auxiliary layer OAL may be located on the step layer STPL. In the second emission area EA2, only the optical auxiliary layer OAL may be located on the reflective electrode RL. The thicknesses of the optical auxiliary layer OAL may be substantially constant in the first emission area EA1, the second emission area EA2 and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be determined based on the wavelength and resonance distance of the light emitted from the first stack layer IL1 of the light-emitting stack IL and the wavelength and resonance distance of the light emitted from the second stack layer IL2.

Each of the light-emitting elements LE may include a first electrode AND, a light-emitting stack IL, and a second electrode CAT.

The first electrode AND of each of the light-emitting elements LE may be located on the respective optical auxiliary layers OAL. Because the connection electrode ANC, the reflective electrode RL and the optical auxiliary layer OAL are sequentially stacked on one another, the first electrode AND of each of the light-emitting elements LE may be located on the upper surface and the side surfaces of the optical auxiliary layer OAL, the side surfaces of the reflective electrode RL, and the side surfaces of the connection electrode ANC. In this manner, the first electrode AND of each of the light-emitting elements LE may come into contact with the side surfaces of the electrode RL and the side surfaces of the connection electrode ANC and may be electrically connected to them. Therefore, it is possible to reduce mask processes compared to a structure in which the first electrode AND of each of the light-emitting elements LE is connected to the reflective electrode RL exposed through a hole penetrating the optical auxiliary layer OAL. As a result, there are advantages that fabrication cost can be saved and the fabrication efficiency can be increased.

The first electrode AND of each of the light-emitting elements LE may be connected to the drain region DA or the source region SA of the pixel transistor PTR through the connection electrode ANC, the first to ninth vias VA1 to VA9, the first to eighth metal layers ML1 to ML8 and the contact terminal CTE.

The ninth insulating film INS9 may include a first portion AA1 that overlaps with the connection electrode ANC in the third direction DR3, and a second portion AA2 that does not overlap with the connection electrode ANC in the third direction DR3. The thickness of the first portion AA1 and the thickness of the second portion AA2 of the ninth insulating film INS9 may be substantially equal to each other.

Alternatively, the thickness of the first portion AA1 of the ninth insulating film INS9 may be greater than the thickness of the second portion AA2. In this instance, a side surface of the first portion AA1 of the ninth insulating film INS9 may be exposed, and the first electrode AND of each of the light-emitting elements LE may be located on the exposed side surface of the first portion AA1 of the ninth insulating film INS9.

The first electrode AND of each of the light-emitting elements LE may be made of one of copper (Cu), aluminum (Al), tungsten (W), molybdenum (Mo), chromium (Cr), gold (Au), titanium (Ti), nickel (Ni) and neodymium (Nd) or an alloy containing any one of them, or a transparent conductive oxide. For example, the first electrode AND of each of the light-emitting elements LE may include, but is not limited to, titanium nitride (TiN), indium tin oxide (ITO), or indium zinc oxide (IZO).

The pixel-defining layer PDL may be located partially on the first electrode AND of each of the light-emitting elements LE. The pixel-defining layer PDL may cover the edge of the first electrode AND of each of the light-emitting elements LE. The pixel-defining layer PDL may define the first emission areas EA1, the second emission areas EA2 and the third emission areas EA3.

The pixel-defining layer PDL may include first to fourth pixel-defining layers PDL1, PDL2, PDL3 and PDL4.

The first pixel-defining layer PDL1 may be located on the first electrode AND of each of the light-emitting elements LE. For example, the first pixel-defining layer PDL1 may cover a part of the upper surface of the first electrode AND located on the optical auxiliary layer OAL. In addition, the first pixel-defining layer PDL1 may cover the first electrode AND which is located on the side surfaces of the connection electrode ANC, the side surfaces of the reflective electrode RL and the side surfaces of the optical auxiliary layer OAL. The first pixel-defining layer PDL1 may be located on the upper surface of the second portion AA2 of the ninth insulating film INS9.

A planarization film PNS is a film for providing a flat surface over the connection electrode ANC, the reflective electrode RL and the optical auxiliary layer OAL.

The planarization film PNS may be located on the first pixel-defining layer PDL1 that covers the first electrode AND located on the side surfaces of the connection electrode ANC, the side surfaces of the reflective electrode RL and the side surfaces of the optical auxiliary layer OAL. The planarization film PNS may be located on the first pixel-defining layer PDL1 located on the second portion AA2 of the ninth insulating film INS9.

The planarization film PNS may be located between the connection electrodes ANC adjacent to each other in the first direction DR1 or the second direction DR2. The planarization film PNS may be located between the reflective electrodes RL adjacent to each other in the first direction DR1 or the second direction DR2. The planarization film PNS may be located between the optical auxiliary layer OAL adjacent to each other in the first direction DR1 or the second direction DR2.

While there is no step layer STPL in the second emission area EA2, a step layer STPL is located in each of the first emission area EA1 and the third emission area EA3. Due to this, the height of the connection electrode ANC, the reflective electrode RL and the optical auxiliary layer OAL in the second emission area EA2 may be smaller than the height of the connection electrode ANC, the reflective electrode RL, the step layer STPL and the optical auxiliary layer OAL in each of the first emission area EA1 and the third emission area EA3. Therefore, the planarization film PNS may cover the upper surface of the first pixel-defining layer PDL1 located on the upper surface of the first electrode AND located in the second emission area EA2.

In contrast, the upper surface of the planarization film PNS may be flatly connected to the upper surfaces of the first electrode AND located in the first emission area EA1 and the third emission area EA3. That is to say, the planarization film PNS may not cover the upper surface of the first pixel-defining layer PDL1 located on the upper surface of the first electrode AND located in each of the first emission area EA1 and the third emission area EA3.

The second pixel-defining layer PDL2 may be located on the first pixel-defining layer PDL1 and the planarization film PNS, the third pixel-defining layer PDL3 may be located on the second pixel-defining layer PDL2, and the fourth pixel-defining layer PDL4 may be located on the third pixel-defining layer PDL3. The first pixel-defining layer PDL1 and the third pixel-defining layer PDL3 are formed of inorganic films such as silicon nitride (SiNx)-based inorganic films, while the second pixel-defining layer PDL2, the fourth pixel-defining layer PDL4 and the planarization film PNS may be formed of silicon oxide (SiOx)-based inorganic films. Because the first pixel-defining layer PDL1 is made of a different material from the planarization film PNS, it may work as a stopper in a process of chemically and mechanically polishing the planarization film PNS.

When the planarization film PNS as well as the second pixel-defining layer PDL2 are formed of a silicon oxide (SiOx)-based inorganic film, the planarization film PNS and the second pixel-defining layer PDL2 may be formed as a single film.

Because the length of the third pixel-defining layer PDL3 in a direction is smaller than the length of the fourth pixel-defining layer PDL4 in the direction, the lower surface of the fourth pixel-defining layer PDL4 may be exposed without being covered by the third pixel-defining layer PDL3. In other words, the third pixel-defining layer PDL3 and the fourth pixel-defining layer PDL4 may have a cross-sectional structure in the shape of an eave or a mushroom.

The light-emitting stack IL may be located on the first electrode AND and the pixel-defining layer PDL. The light-emitting stack IL may include a first stack layer IL1 and a second stack layer IL2 that emit different lights. When the light-emitting stack IL has a two-tandem structure, one of the first stack layer IL1 and the second stack layer IL2 may emit light including a wavelength range of one of the first light, the second light and the third light, while the other one may emit light including wavelength ranges of the other two lights. For example, the first stack layer IL1 may emit light including the wavelength range of the first light and the wavelength range of the third light, while the second stack layer IL2 may emit light including the wavelength range of the second light. The first light may be light of a blue wavelength band, the second light may be light of a green wavelength band, and the third light may be light of a red wavelength band.

A charge generation layer may be located between the first stack layer IL1 and the second stack layer IL2 to supply charges to the second stack layer IL2 and electrons to the first stack layer IL1. The charge generation layer may include an n-type charge generation layer that supplies electrons to the first stack layer IL1, and a p-type charge generation layer that supplies holes to the second stack layer IL2. The n-type charge generation layer may include a dopant of a metallic material.

Because the first stack layer IL1 is not formed on the lower surface of the fourth pixel-defining layer PDL4 that is exposed and not covered by the third pixel-defining layer PDL3, it may be broken by the cross-sectional structure of the third pixel-defining layer PDL3 and the fourth pixel-defining layer PDL4 in the shape of the eave or mushroom. When this happens, the first hole transport layer of the first stack layer IL1 as well as the charge generation layer CGL located between the first stack layer IL1 and the second stack layer IL2 may also be disconnected. In addition, although the second stack layer IL2 is connected without being disconnected in the example shown in FIG. 8, the second hole transport layer of the second stack layer IL2 may be disconnected while the second electron transport layer of the second stack layer IL2 may be connected without being disconnected. Therefore, it may be possible to prevent or reduce leakage current from flowing between the adjacent emission areas EA1, EA2 and EA3 through the first hole transport layer of the first stack layer IL1, the second hole transport layer of the second stack layer IL2, and the charge generation layer CGL. Accordingly, it is possible to avoid that the light-emitting stack IL in the adjacent emission areas EA1, EA2 and EA3 are affected by the current and emit light other than the originally intended light.

Although the light-emitting stack IL has a two-tandem structure including two stack layers IL1 and IL2 in the example shown in FIG. 8, the embodiments of the present disclosure are not limited thereto. For example, the light-emitting stack IL may have a three-tandem structure including three stack layers as shown in FIG. 7. In this instance, the height of the third pixel-defining layer PDL3 may be adjusted so that the charge generation layer between the first stack layer IL1 and the second stack layer IL2, and the charge generation layer between the second stack layer IL2 and the third stack layer IL3 are disconnected. Alternatively, as shown in FIG. 7, trenches TRC penetrating the first pixel-defining layer PDL1, the planarization film PNS, the second pixel-defining layer PDL2 and the third pixel-defining layer PDL3 may be added. In this instance, the trenches TRC may penetrate at least partially the ninth insulating film INS9, but the embodiments of the present disclosure are not limited thereto.

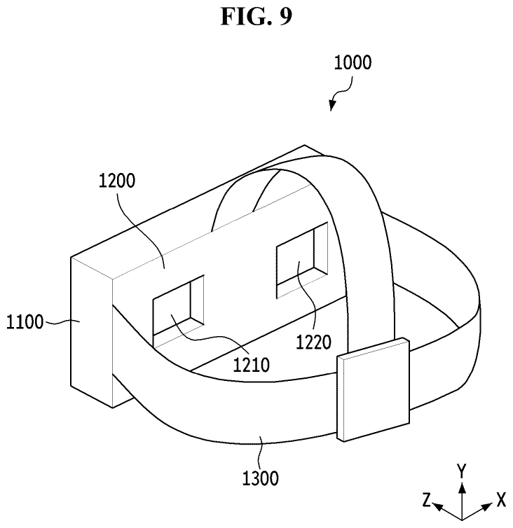

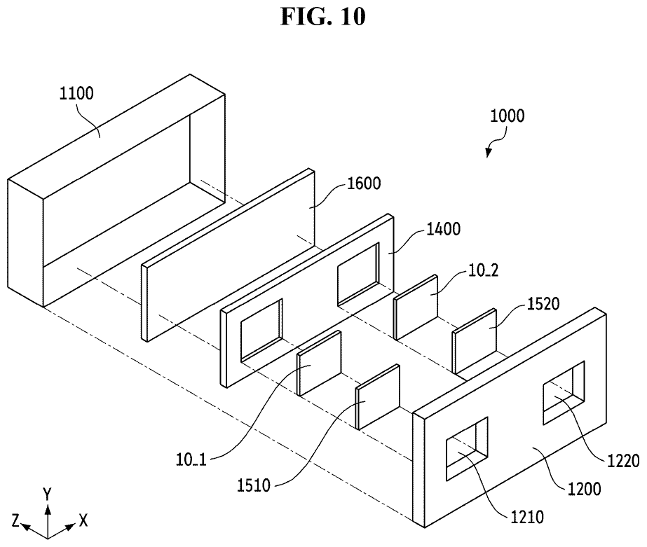

FIG. 9 is a perspective view showing an example of an electronic device. FIG. 10 is an exploded perspective view for illustrating the electronic device of FIG. 9.

Referring to FIGS. 9 and 10, an electronic device 1000 according to some embodiments includes a first display device 10_1, a second display device 10_2, a display device housing 1100, a housing cover 1200, a first eyepiece 1210, a second eyepiece 1220, a head strap band 1300, a middle frame 1400, a first optical member 1510, a second optical member 1520, and a control circuit board 1600.

The first display device 10_1 provides images to a user's left eye, and the second display device 10_2 provides images to the user's right eye. The first display device 10_1 and the second display device 10_2 are substantially identical to the display device 10 described above with reference to FIGS. 1 to 8; and, therefore, some redundant description may be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600, and may be located between the second display device 10_2 and the control circuit board 1600. The middle frame 1400 serves to support and fix the first display device 10_1, the second display device 10_2 and the control circuit board 1600.

The control circuit board 1600 may be located between the middle frame 1400 and the display device housing 1100. The control circuit board 1600 may be connected to the first display device 10_1 and the second display device 10_2 through a connector. The control circuit board 1600 may convert an image source input from the outside into digital video data DATA and may transmit the digital video data DATA to the first display device 10_1 and the second display device 10_2 through the connector.

The control circuit board 1600 may transmit digital video data DATA associated with a left eye image optimized for the user's left eye to the first display device 10_1, and may transmit digital video data DATA associated with a right eye image optimized for the user's right eye to the second display device 10_2. Alternatively, the control circuit board 1600 may transmit the same digital video data DATA to the first display device 10_1 and the second display device 10_2.

The display device housing 1100 accommodates the first display device 10_1, the second display device 10_2, the middle frame 1400, the first optical member 1510, the second optical member 1520, and the control circuit board 1600. The housing cover 1200 is arranged to cover the open face of the display device housing 1100. The housing cover 1200 may include the first eyepiece 1210 where the user's left eye is placed, and the second eyepiece 1220 where the user's right eye is placed. Although the first eyepiece 1210 and the second eyepiece 1220 are separately arranged in the example shown in FIGS. 9 and 10, the embodiments of the present disclosure are not limited thereto. The first eyepiece 1210 and the second eyepiece 1220 may be combined into a single element.

The first eyepiece 1210 may be aligned with the first display device 10_1 and the first optical member 1510, and the second eyepiece 1220 may be aligned with the second display device 10_2 and the second optical member 1520. Therefore, a user may see virtual images of images on the first display device 10_1 magnified by the first optical member 1510 through the first eyepiece 1210, and virtual images of images on the second display device 10_2 magnified by the second optical member 1520 through the second eyepiece 1220.

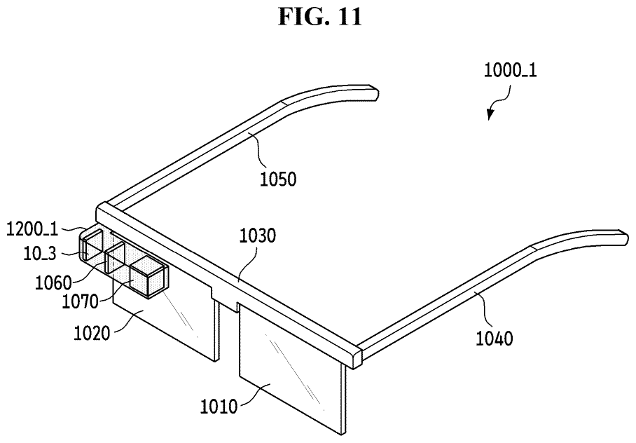

The head strap band 1300 fixes the housing 1100 to the user's head so that the first eyepiece 1210 and the second eyepiece 1220 of the housing cover 1200 remain in line with the user's left and right eyes, respectively. By implementing a light and small display device housing 1200, the electronic device 1000 may include an eyeglass frame as shown in FIG. 11 instead of a head strap band 800.

FIG. 11 is a perspective view showing another example of an electronic device.

Referring to FIG. 11, the electronic device 1000_1 according to some embodiments may be a glasses-type display device with a light and small display device housing 1200_1. The electronic device 1000_1 according to some embodiments may include a display device 10_3, a left-eye lens 1010, a right-eye lens 1020, a support frame 1030, eyeglass temples 1040 and 1050, an optical member 1600, an optical path conversion member 1070, and a display device housing 1200_1.

The display device housing 1200_1 may include the display device 10_3, the optical member 1600, and the optical path conversion member 1070. The images displayed on the display device 10_3 may be enlarged by the optical member 1600, and the optical path of the images are converted by the optical path conversion member 1070 to be provided to the user's right eye through the right eye lens 1020. As a result, the user can see, with the right eye, augmented reality images that combine virtual images displayed on the display device 10_3 and real world images viewed through the right eye lens 1020.

Although the display device housing 1200_1 is located at the right end of the support frame 1030 in the example shown in FIG. 11, the embodiments of the present disclosure are not limited thereto. For example, the display device housing 1200_1 may be located at the left end of the support frame 1030. In such case, images displayed on the display device 10_3 may be provided to the user's left eye. Alternatively, the display device housing 1200_1 may be located at both the left and right ends of the support frame 1030, respectively. In such case, the user can watch images displayed on the display device 10_3 through both the left and right eyes.

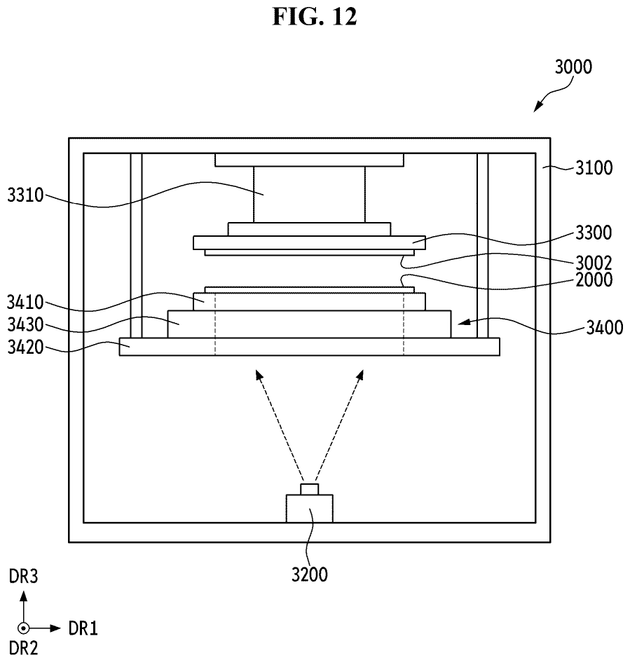

FIG. 12 is a view showing a deposition apparatus according to some embodiments of the present disclosure.

Referring to FIG. 12, a deposition apparatus 3000 may be used to form light-emitting material layers on a backplane substrate 3002 in a process of fabricating a display panel 100 (see FIG. 1). For example, as shown in FIG. 7, a semiconductor backplane SBP and a light-emitting element backplane EBP may be located on the backplane substrate 3002, and a reflective electrode RL and a tenth insulating film INS10 may be located on the light-emitting element backplane EBP. An eleventh insulating film INS11 may be located on the tenth insulating film INS10. Electrode patterns, e.g., anode electrodes AND may be located on the eleventh insulating film INS11, and the anode electrodes AND may be electrically connected to the reflective electrode RL through vias VA10. The deposition apparatus 3000 may be used to form a light-emitting stack IL on the electrode patterns.

The deposition apparatus 3000 can include a deposition source 3200 for providing a vapor deposition material on a backplane substrate 3002, a deposition mask 2000 located above the deposition source 3200, and a substrate chuck 3300 located above the deposition mask 2000 to support the backplane substrate 3002 so that the backplane substrate 3002 faces the deposition mask 2000. That is to say, the substrate chuck 3300 may support the backplane substrate 3002 so that the front surface of the backplane substrate 3002 faces downward, and may place the backplane substrate 3002 above the deposition mask 2000 to perform a deposition process. The substrate chuck 3300 may be supported by a support member 3310, and a permanent magnet may be located inside the support member 3310.

The deposition source 3200, the deposition mask 2000 and the substrate chuck 3300 may be located in a process chamber 3100. The process chamber 3100 may have an internal space, and a deposition process for forming a deposition material layer on the backplane substrate 3002 may be performed in the internal space of the process chamber 3200. According to some embodiments, the process chamber 3100 may be connected to a vacuum pump. Vacuum atmosphere may be created in the internal space of the process chamber 3100 by the vacuum pump. An opening may be formed on a side wall of the process chamber 3100 for the backplane substrate 3002 and the deposition mask 2000 to come in and out, and the opening may be opened and closed by a gate valve.

A deposition material may be stored in the deposition source 3200. The deposition source 3200 may evaporate a deposition material, such as an organic material, an inorganic material and a conductive material, toward the backplane substrate 3002. The evaporated deposition material may be deposited on the backplane substrate 3002 through the deposition mask 2000. For example, the deposition source 3200 may evaporate an organic material for forming light-emitting material layers on the backplane substrate 3002, and the evaporated organic material may be deposited on electrode patterns on the backplane substrate 3002 through the deposition mask 2000.

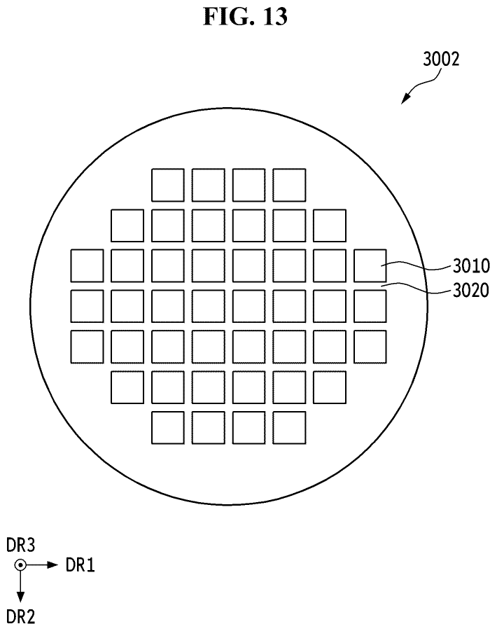

FIG. 13 is a bottom view showing the backplane substrate shown in FIG. 12.

Referring to FIG. 13, the backplane substrate 3002 may include a plurality of display cell areas 3010, and a scribe lane area 3020 between the display cell areas 3010. The display cell areas 3010 may be arranged in a matrix pattern along the first direction DR1 and the second direction DR2, as shown in FIG. 13. The display cell areas 3010 may become a plurality of individual display panels 100 (see FIG. 1) via a dicing process after the process of fabricating a display has been completed. For example, the display cell areas 3010 may be arranged in a matrix pattern along the first horizontal direction DR1 and the second horizontal direction DR2 perpendicular to the first horizontal direction DR1.

Each of the display cell areas 3010 may include a semiconductor backplane SBP, a light-emitting element backplane EBP located on the semiconductor backplane SBP, a reflective electrode RL located on the light-emitting element backplane EBP, and the eleventh insulating film INS11 located on the reflective electrode RL. In addition, each of the display cell areas 3010 may include a plurality of electrode patterns, e.g., a plurality of anode electrodes AND, arranged on the eleventh insulating film INS11, and the anode electrodes AND may be connected to the reflective electrode layer RL through a plurality of vias VA10. The electrode patterns of the display cell areas 3010 may be arranged on the front surface of the backplane substrate 3002. The substrate chuck 3300 may grip the rear surface of the backplane substrate 3002 so that the electrode patterns of the display cell areas 3010 face downward, i.e., face the deposition source 3200.

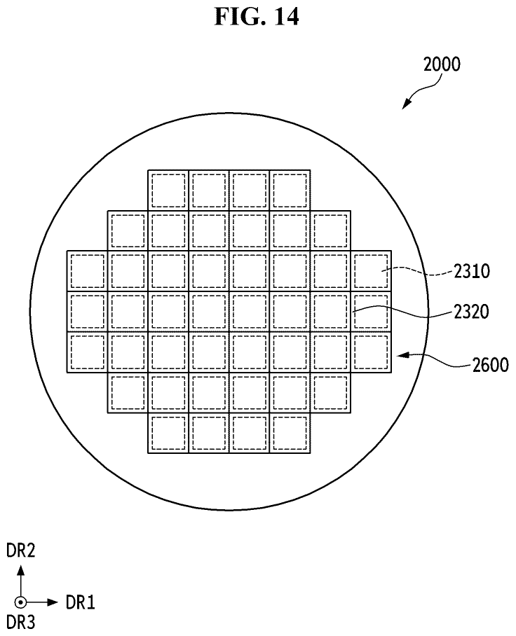

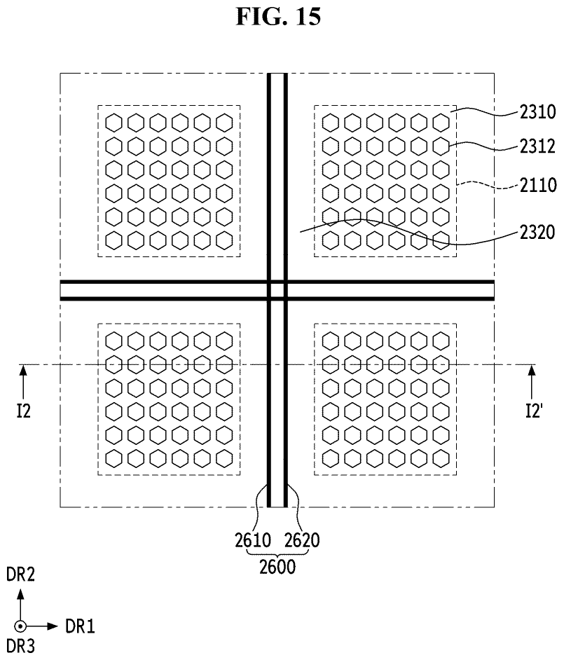

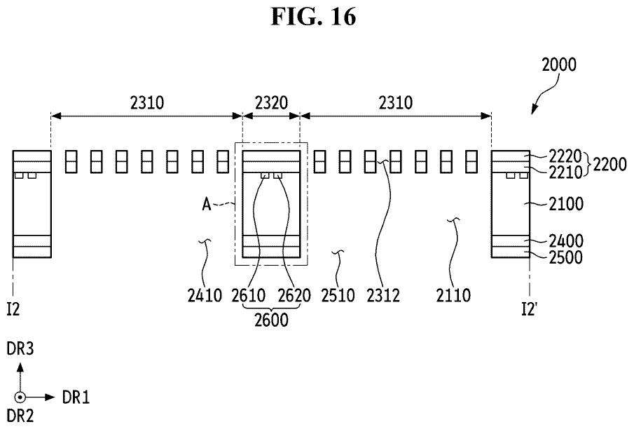

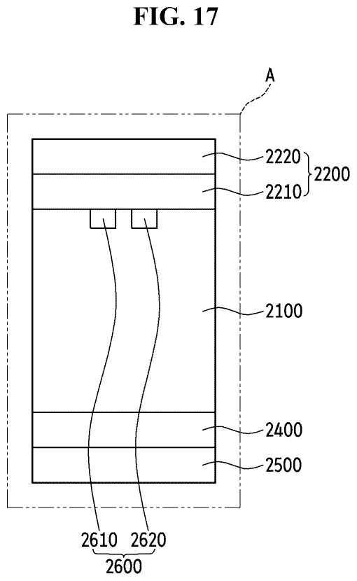

FIG. 14 is a plan view showing a deposition mask according to some embodiments of the present disclosure. FIG. 15 is an enlarged plan view showing mask cell areas illustrated in FIG. 14. FIG. 16 is a cross-sectional view showing an example of a deposition mask cut along the line I2-I2′ of FIG. 15. FIG. 17 is an enlarged view of portion A of FIG. 16.

Referring to FIGS. 14 to 17, a deposition mask 2000 according to some embodiments of the present disclosure may include a mask frame 2100, a membrane 2200, a first rear inorganic layer 2400, a second rear inorganic layer 2500, and an electrode pattern portion 2600.

The mask frame 2100 may have cell openings 2110. The cell opening 2110 may be provided in plural numbers, and the plurality of cell openings 2110 may be spaced apart from each other in the first direction DR1 and the second direction DR2. In other words, the plurality of cell openings 2110 may be arranged in a matrix form along the first direction DR1 and the second direction DR2. The plurality of cell openings 2110 may be overlapped with a mask cell area 2310 to be described later. The mask frame 2100 may be provided as a monocrystalline silicon substrate. The cell openings 2110 may be formed via a wet etching process using tetramethyl ammonium hydroxide (TMAH) or potassium hydroxide (KOH). The crystal direction of the monocrystalline silicon substrate provided as the mask frame 2100 may be the third direction DR3 of the deposition mask 2000.

The membrane 2200 may be located on the upper portion of the mask frame 2100. The membrane 2200 may include the mask cell areas 2310, respectively corresponding to the display cell areas 3010 of the backplane substrate 3002, and a grid area 2320 excluding the mask cell areas 2310.

The mask cell areas 2310, as shown in FIG. 14, may be arranged in a matrix form along the first direction DR1 and the second direction DR2. For example, the mask cell areas 2310 may be arranged in a matrix form along a first horizontal direction DR1 and a second horizontal direction DR2 perpendicular to the first horizontal direction DR1 and be arranged to respectively correspond to the display cell areas 3010. In addition, the mask cell areas 2310 may be overlapped with the cell openings 2110.

The grid area 2320 may be an area excluding the mask cell areas 2310 in the membrane 2200. The grid area 2320 may be located between the mask cell areas 2310.

In addition, the membrane 2200 may include an inorganic layer 2210 and a nitride layer 2220.

The inorganic layer 2210 may be located on the upper portion of the mask frame 2100. In other words, the inorganic layer 2210 may be located on the upper portion of the mask frame 2100 so that the lower surface thereof is in contact with the upper surface of the mask frame 2100. The inorganic layer 2210 may be formed of a material having an etching selectivity with respect to the nitride layer 2220 and the mask frame 2100. For example, the inorganic layer 2210 may include silicon oxide (SiOx).

The nitride layer 2220 may be located on the upper portion of the inorganic layer 2210. In other words, the nitride layer 2220 may be located on the upper portion of the inorganic layer 2210 so that the lower surface thereof is in contact with the upper surface of the inorganic layer 2210. The nitride layer 2220 may include silicon nitride (SiNx).

Each of the mask cell areas 2310 of the membrane 2200 may include a plurality of pixel openings 2312 exposing the anode electrodes AND in the deposition process. The mask cell areas 2310 maybe exposed toward a deposition source 3200 through the cell openings 2110, and the pixel openings 2312 may penetrate the membrane 2200 to be connected to the cell openings 2110. In other words, the pixel openings 2312 may be formed to penetrate the inorganic layer 2210 and the nitride layer 2220 to be connected to the cell openings 2110.

The first rear inorganic layer 2400 may be located on the lower portion of the mask frame 2100. In other words, the first rear inorganic layer 2400 may be located on the lower portion of the mask frame 2100 so that the upper surface thereof is in contact with the lower surface of the mask frame 2100. In the first rear inorganic layer 2400, first rear openings 2410 in communication with the cell openings 2110 may be formed. The first rear inorganic layer 2400 may include the same material as the inorganic layer 2210 of the membrane 2200. For example, the first rear inorganic layer 2400 may include silicon oxide (SiOx).

The second rear inorganic layer 2500 may be located on the lower portion of the first rear inorganic layer 2400. In other words, the second rear inorganic layer 2500 may be located on the lower portion of the first rear inorganic layer 2400 so that the upper surface thereof is in contact with the lower surface of the first rear inorganic layer 2400. In the second rear inorganic layer 2500, second rear openings 2510 in communication with the cell openings 2110 and the first rear openings 2410 may be formed. The second rear inorganic layer 2500 may include the same material as the nitride layer 2220 of the membrane 2200. For example, the second rear inorganic layer 2500 may include silicon nitride (SiNx).

The electrode pattern portion 2600 may be located on the mask frame 2100. The electrode pattern portion 2600 may be arranged to surround the plurality of cell openings 2110 while in a state of being spaced apart from the plurality of cell openings 2110. For example, the electrode pattern portion 2600 may extend in the first direction DR1 and the second direction DR2 on the mask frame 2100 to surround the cell openings 2110. The electrode pattern portion 2600 may extend in the first direction DR1 and the second direction DR2 between the cell openings 2110 to surround the cell openings 2110. Because the electrode pattern portion 2600 is arranged to surround the cell openings 2110, the electrode pattern portion 2600 may overlap the grid area 2320 of the membrane 2200.

The electrode pattern portion 2600 may include a first electrode pattern 2610 and a second electrode pattern 2620.

The first electrode pattern 2610 may be located on the mask frame 2100 to be spaced apart from the cell openings 2110 to surround the plurality of cell openings 2110. For example, the first electrode pattern 2610 may extend in the first direction DR1 and the second direction DR2 on the mask frame 2100 to surround the cell openings 2110. The first electrode pattern 2610 may be arranged to be introduced into the interior of the mask frame 2100 from the upper surface of the mask frame 2100. For example, from the upper surface of the mask frame, the first electrode pattern 2610 may be introduced into the mask frame 2100 in the thickness direction by a doping process. Because the first electrode pattern 2610 is introduced into the interior of the mask frame 2100 from the upper surface of the mask frame 2100, the first electrode pattern 2610 may be located on the lower portion of the inorganic layer 2210 of the membrane 2200.

The first electrode pattern 2610 may be provided as a pattern formed of a conductive metal material and may receive current from a separate power supply unit. For example, the first electrode pattern 2610 may receive positive current from a separate power supply unit.

The second electrode pattern 2620 may be located on the mask frame 2100 to be spaced apart from the cell openings 2110 and the first electrode pattern 2610 to surround the plurality of cell openings 2110. For example, the second electrode pattern 2620 may extend in the first direction DR1 and the second direction DR2 to surround the cell openings 2110 while in a state of being spaced apart from the first electrode pattern 2610 on the mask frame 2100. The second electrode pattern 2620 may be formed to be introduced into the interior of the mask frame 2100 from the upper surface of the mask frame 2100. For example, from the upper surface of the mask frame 2100, the second electrode pattern 2620 may be introduced into the mask frame 2100 in the thickness direction by a doping process. Because the second electrode pattern 2620 is introduced into the interior of the mask frame 2100 from the upper surface of the mask frame 2100, the second electrode pattern 2620 may be located on the lower portion of the inorganic layer 2210 of the membrane 2200.

The second electrode pattern 2620 may be provided as a pattern formed of a conductive metal material and may receive current from a separate power supply unit. For example, the second electrode pattern 2620 may receive a current having the opposite polarity from the first electrode pattern 2610. For example, the second electrode pattern 2620 may receive negative current from a separate power supply unit.

Like described above, currents of different polarities are supplied to the first electrode pattern 2610 and the second electrode pattern 2620, and an electric field may be generated near the first electrode pattern 2610 and the second electrode pattern 2620, thereby forming an electrostatic attraction.

The first electrode pattern 2610 and the second electrode pattern 2620 may extend in a linear form in the first direction DR1 and the second direction DR2. In addition, the first electrode pattern 2610 and the second electrode pattern 2620 may extend in a curved shape or a shape bent multiple times in the first direction DR1 and the second direction DR2. Because the extension length of the first electrode pattern 2610 and the second electrode pattern 2620 is formed longer when extended in a curved shape or a shape that is bent multiple times than when extended in a linear form, a higher electrostatic attraction may be formed when the first electrode pattern 2610 and the second electrode pattern 2620 are extended in a curved shape or a shape that is bent multiple times.

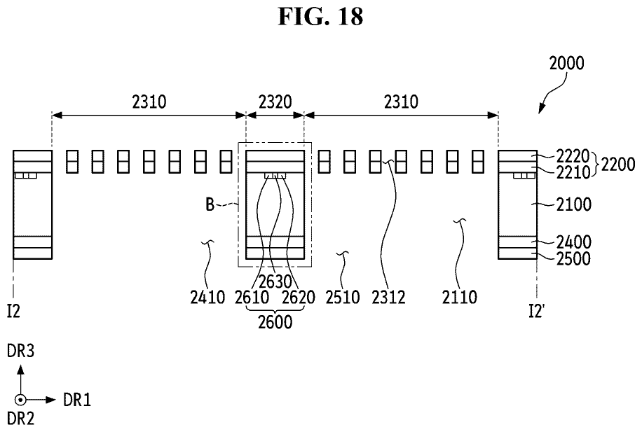

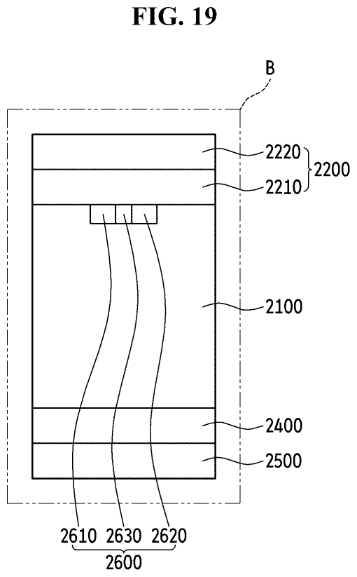

FIG. 18 is a cross-sectional view showing another example of a deposition mask cut along the line I2-I2′ of FIG. 15. FIG. 19 is an enlarged view of portion B of FIG. 18.

Referring to FIGS. 18 and 19, the electrode pattern portion 2600 may further include an insulating pattern 2630.

The insulating pattern 2630 may be located between the first electrode pattern 2610 and the second electrode pattern 2620 on the mask frame 2100. The insulating pattern 2630 may be introduced into the interior of the mask frame 2100 from the upper surface of the mask frame 2100 and be located between the first electrode pattern 2610 and the second electrode pattern 2620. The insulating pattern 2630 may extend in the first direction DR1 and the second direction DR2 to insulate between the first electrode pattern 2610 and the second electrode pattern 2620. The insulating pattern 2630 may include an insulating material. For example, the insulating pattern 2630 may include silicon oxide (SiOx). The insulating pattern 2630 may prevent or reduce current leaking between the first electrode pattern 2610 and the second electrode pattern 2620.

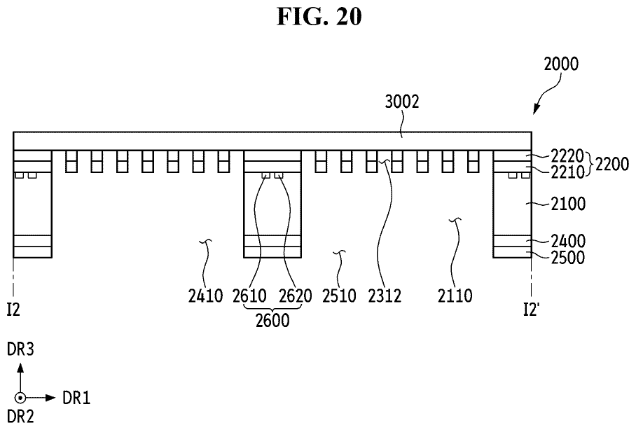

FIG. 20 is a cross-sectional view showing a state in which a deposition mask according to some embodiments of the present disclosure is in contact with a backplane substrate.

Referring to FIG. 20, a deposition mask 2000 may be in contact with a backplane substrate 3002 in order to deposit a deposition material on the backplane substrate 3002. When a current is supplied to the electrode pattern portion 2600 in a state where the deposition mask 2000 is in contact with the backplane substrate 3002, an electric field may be generated in the electrode pattern portion 2600 to form an electrostatic attraction. For example, when a positive current is supplied to the first electrode pattern 2610 and a negative current is supplied to the second electrode pattern 2620, an electric field may be generated in the vicinity of the first electrode pattern 2610 and the second electrode pattern 2620 by supplying currents of different polarities. As described above, the electric field generated in the vicinity of the first electrode pattern 2610 and the second electrode pattern 2620 may form an electrostatic attraction, and the adhesion between the membrane 2200 of the deposition mask 2000 and the backplane substrate 3002 may be increased by the electrostatic attraction formed by the generated electric field.

The display device manufactured by using the deposition mask 2000 according to some embodiments of the present disclosure may be applied to a variety of electronic devices. An electronic device according to some embodiments includes the display device described above, and may further include a module or device having additional features in addition to the display device.

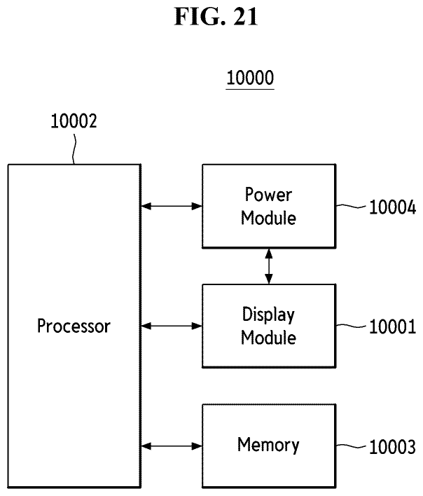

FIG. 21 is a block diagram of an electronic device according to some embodiments of the present disclosure.

An electronic device 10000 according to some embodiments may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

Data information necessary for an operation of the processor 10002 or the display module 10001 may be stored in the memory 10003. When the processor 10002 executes an application stored in the memory 10003, image data signals and/or input control signals may be transmitted to the display module 10001 may, and the display module 10001 may process the provided signals and output image information through a display screen.

The power module 10004 may include a power supply module, such as a power adapter or a battery device, and a power conversion module that converts power supplied by the power supply module to generate power required for an operation of the electronic device 10000.

At least one of the components of the electronic device 10000 described above may be included in the display device according to the above-described example embodiments. In addition, some of the individual modules functionally included within one module may be included within the display device, while others may be provided separately from the display device. For example, the display device includes the display module 10001, and the processor 10002, the memory 10003 and the power module 10004 may be provided in the form of other devices within the electronic device 10000 other than the display device.

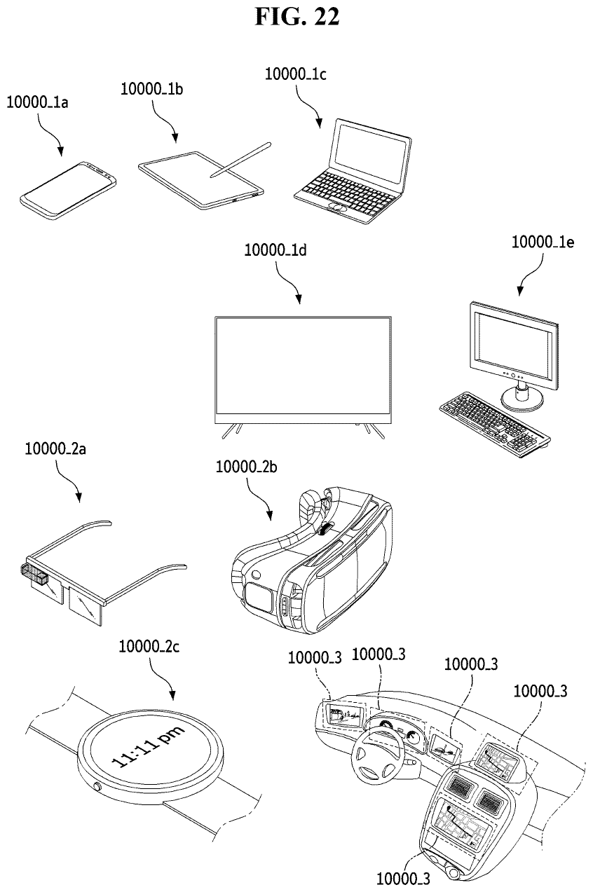

FIG. 22 is a view showing electronic devices according to a variety of embodiments of the present disclosure.

Referring to FIG. 22, various electronic devices 1 to which the display device according to the example embodiments is applied may include not only an image display electronic device such as a smart phone 10000_1a, a tablet PC 10000_1b, a laptop 10000_1c, a TV 10000_1d, and a desk monitor 10000_1e, but also a wearable electronic device including a display module such as a smart glasses 10000_2a, a head mounted display 10000_2b, a smart watch 10000_2c, and the like, and a vehicle electronic device 10000_3 including a display module such as a Center Information Display (CID), a room mirror display, etc., located on a vehicle's instrument panel, center fascia, or dashboard.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A deposition mask comprising:
a mask frame in which a cell opening is formed;
a membrane on the upper portion of the mask frame; and
an electrode pattern portion on the mask frame.

2. The deposition mask of claim 1, wherein the electrode pattern portion surrounds the cell opening in a state of being spaced apart from the cell opening.

3. The deposition mask of claim 1, wherein the cell opening is provided in plural numbers, and
the electrode pattern portion is between the cell openings.

4. The deposition mask of claim 1, wherein the electrode pattern portion is introduced into the interior of the mask frame from the upper surface of the mask frame.

5. The deposition mask of claim 1,
wherein the membrane is divided into a mask cell area on the upper portion of the cell opening and a grid area on the upper portion of the mask frame excluding the mask cell area,
and the electrode pattern portion overlaps the grid area.

6. The deposition mask of claim 1,
wherein the membrane comprises:
an inorganic layer on the upper portion of the mask frame; and
a nitride layer on the upper portion of the inorganic layer,
wherein the electrode pattern portion is on the lower portion of the inorganic layer.

7. The deposition mask of claim 1,
wherein the electrode pattern portion comprises:
a first electrode pattern; and
a second electrode pattern spaced apart from the first electrode pattern and having the opposite polarity from the first electrode pattern.

8. The deposition mask of claim 7, wherein the electrode pattern portion further comprises:
an insulating pattern between the first electrode pattern and the second electrode pattern.

9. The deposition mask of claim 1,
wherein the cell opening is provided in plural numbers,
the plurality of cell openings area spaced apart in a first direction and a second direction intersecting the first direction,
and the electrode pattern portion extends in the first direction and the second direction to surround the plurality of cell openings.

10. The deposition mask of claim 9, wherein the electrode pattern portion extends in a linear form in the first direction and second direction.

11. The deposition mask of claim 9,
wherein the electrode pattern portion extends in a curved shape in the first direction and second direction.

12. An electronic device including a display device manufactured by a deposition mask,
wherein the deposition mask comprises:
a mask frame in which a cell opening is formed;
a membrane on the upper portion of the mask frame; and
an electrode pattern portion on the mask frame.

13. The electronic device of claim 12, wherein the electrode pattern portion surrounds the cell opening in a state of being spaced apart from cell opening.

14. The electronic device of claim 12, wherein the cell opening is provided in plural numbers, and
the plurality of cell openings are between the cell openings.

15. The electronic device of claim 12, wherein the electrode pattern portion is introduced into the interior of the mask frame from the upper surface of the mask frame.

16. The electronic device of claim 12, wherein the electrode pattern portion comprises:
a first electrode; and
a second electrode pattern spaced apart from the first electrode pattern and having the opposite polarity from the first electrode pattern.

17. The electronic device of claim 16, wherein the electrode pattern portion further comprises:
an insulating pattern between the first electrode pattern and the second electrode pattern.

18. The electronic device of claim 12, wherein the cell opening is provided in plural numbers,
the plurality of cell openings are spaced apart in a first direction and a second direction intersecting the first direction,
and the electrode pattern portion extends in the first direction and the second direction to surround the plurality of cell openings.

19. The electronic device of claim 18, wherein the electrode pattern portion extends in a linear form in the first direction and second direction.

20. The electronic device of claim 18, wherein the electrode pattern portion extends in a curved form in the first direction and second direction.
